(19) United States
(12) Patent Application Publication
(10) Pub. No.: US 2026/0082923 A1
(43) Pub. Date: Mar. 19, 2026

(54) SEMICONDUCTOR DEVICE AND VEHICLE

(71) Applicant: Rohm Co., Ltd., Kyoto-shi (JP)

(72) Inventors: Koshun SAITO, Kyoto-shi (JP); Momoko NISHINO, Kyoto-shi (JP)

(21) Appl. No.: 19/400,369

(22) Filed: Nov. 25, 2025

Related U.S. Application Data
(63) Continuation of application No. PCT/JP2024/017605, filed on May 13, 2024.

(30) Foreign Application Priority Data
Jun. 2, 2023 (JP) 2023-091932

(51) Int. Cl. H10W 42/00

(52) U.S. Cl. CPC H10W 42/121; H10W 70/411; H10W 70/481; H10W 74/111

(57) ABSTRACT

A semiconductor device includes a semiconductor element, a first lead including a die pad portion, and a sealing resin covering the semiconductor element and a portion of the first lead. The die pad portion includes a first obverse surface facing a first side in a thickness direction and supporting the semiconductor element, a first reverse surface facing a second side in the thickness direction, a first side surface facing a first side in a first direction perpendicular to the thickness direction, and a plurality of first recesses each recessed from both the first reverse surface and the first side surface. The first reverse surface is exposed from the sealing resin, and the first recesses are arranged at intervals in a second direction perpendicular to the thickness direction and the first direction.

### TECHNICAL FIELD

The present disclosure relates to a semiconductor device and a vehicle provided with the semiconductor device.

### BACKGROUND ART

Semiconductor devices provided with semiconductor elements are proposed in various configurations. WO 2022/014387 discloses an example of a conventional semiconductor device. The semiconductor device disclosed in the document includes a lead, a semiconductor element, and a sealing resin. The semiconductor element is mounted on the lead (die pad). The sealing resin covers a portion of the lead and the semiconductor element. The semiconductor element is mounted on the obverse surface of the die pad. The reverse surface of the die pad, which faces away from the obverse surface, is exposed from the sealing resin. This configuration allows the heat generated by the semiconductor element to be efficiently dissipated from the reverse surface of the die pad.

The semiconductor device described above is subject to thermal expansion and contraction in various regions due to heat generated by the semiconductor element. The sealing resin has a greater linear expansion coefficient than either the semiconductor element or the lead. The difference in their linear expansion coefficients causes the sealing resin to undergo thermal contraction, which can generate significant stress near the perimeter of the semiconductor element. This can cause peeling or other defects between the die pad, which supports the semiconductor element, and the sealing resin, which is in contact with the die pad.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view of the main portion of the semiconductor device according to the first embodiment of the present disclosure.

FIG. 5 is a perspective view of the main portion of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a side view of the semiconductor device according to the first embodiment of the present disclosure.

FIG. 10 is a plan view of the main portion of the semiconductor device according to the first embodiment of the present disclosure.

FIG. 11 is a bottom view of the main portion of the semiconductor device according to the first embodiment of the present disclosure.

FIG. 12 is a sectional view taken along line XII-XII in FIG. 11.

FIG. 13 is a sectional view taken along line XIII-XIII in FIG. 11.

FIG. 14 is a sectional view taken along line XIV-XIV in FIG. 11.

FIG. 15 is a sectional view taken along line XV-XV in FIG. 11.

FIG. 16 is a sectional view of the semiconductor device in use according to the first embodiment of the present disclosure.

FIG. 17 is a schematic view of a vehicle provided with the semiconductor device according to the first embodiment of the present disclosure.

FIG. 18 is a perspective view of a semiconductor device according to a first variation of the first embodiment of the present disclosure.

FIG. 19 is a perspective view of the main portion of the semiconductor device according to the first variation of the first embodiment of the present disclosure.

FIG. 20 is a plan view of the main portion of the semiconductor device according to the first variation of the first embodiment of the present disclosure.

FIG. 21 is a perspective view of a semiconductor device according to a second variation of the first embodiment of the present disclosure.

FIG. 22 is a perspective view of the main portion of the semiconductor device according to the second variation of the first embodiment of the present disclosure.

FIG. 23 is a plan view of the main portion of the semiconductor device according to the second variation of the first embodiment of the present disclosure.

FIG. 24 is a bottom view of the main portion of the semiconductor device according to the second variation of the first embodiment of the present disclosure.

FIG. 25 is a sectional view taken along line XXV-XXV in FIG. 24.

FIG. 26 is a sectional view taken along line XXVI-XXVI in FIG. 24.

FIG. 27 is a perspective view of a semiconductor device according to a second embodiment of the present disclosure.

FIG. 28 is a perspective view of the main portion of the semiconductor device according to the second embodiment of the present disclosure.

FIG. 29 is a plan view of the main portion of the semiconductor device according to the second embodiment of the present disclosure.

FIG. 30 is a bottom view of the main portion of the semiconductor device according to the second embodiment of the present disclosure.

FIG. 31 is a sectional view taken along line XXXI-XXXI in FIG. 30.

FIG. 32 is a sectional view taken along line XXXII-XXXII in FIG. 30.

FIG. 33 is a perspective view of the main portion of the semiconductor device according to a first variation of the second embodiment.

FIG. 34 is a plan view of the main portion of the semiconductor device according to the first variation of the second embodiment.

FIG. 35 is a sectional view of the semiconductor device according to the first variation of the second embodiment, corresponding to the section shown in FIG. 31.

FIG. 36 is a sectional view of the semiconductor device according to the first variation of the second embodiment, corresponding to the section shown in FIG. 32.

### DETAILED DESCRIPTION OF EMBODIMENTS

The following specifically describes preferred embodiments of the present disclosure with reference to the drawings.

In the present disclosure, the terms such as “first”, “second”, “third”, and so on are used only as labels and not to imply an order of the items referred to by the terms.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B.” Further, the expression “An object A is positioned on an object B” implies the situation where, unless otherwise specifically noted, “the object A is positioned on the object B, in contact with the object B”, and “the object A is positioned on the object B, with something else interposed between the object A and the object B.” The expression “An object A overlaps an object B as viewed in a certain direction” implies the situation where, unless otherwise specifically noted, “the object A overlaps the entirety of the object B”, and “the object A overlaps a portion of the object B.” In the present disclosure, the expression “A surface A faces in a direction B (or a first side or a second side in the direction B)” is not limited, unless otherwise specifically noted, to the situation where the surface A forms an angle of 90° with the direction B but includes the situation where the surface A is inclined relative to the direction B.

### First Embodiment

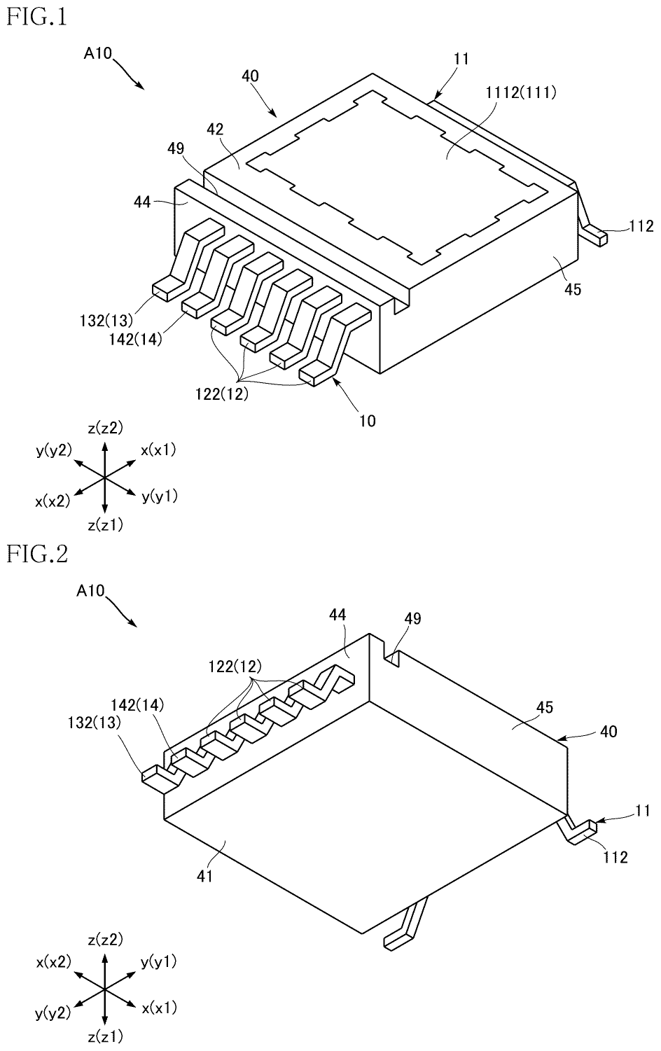

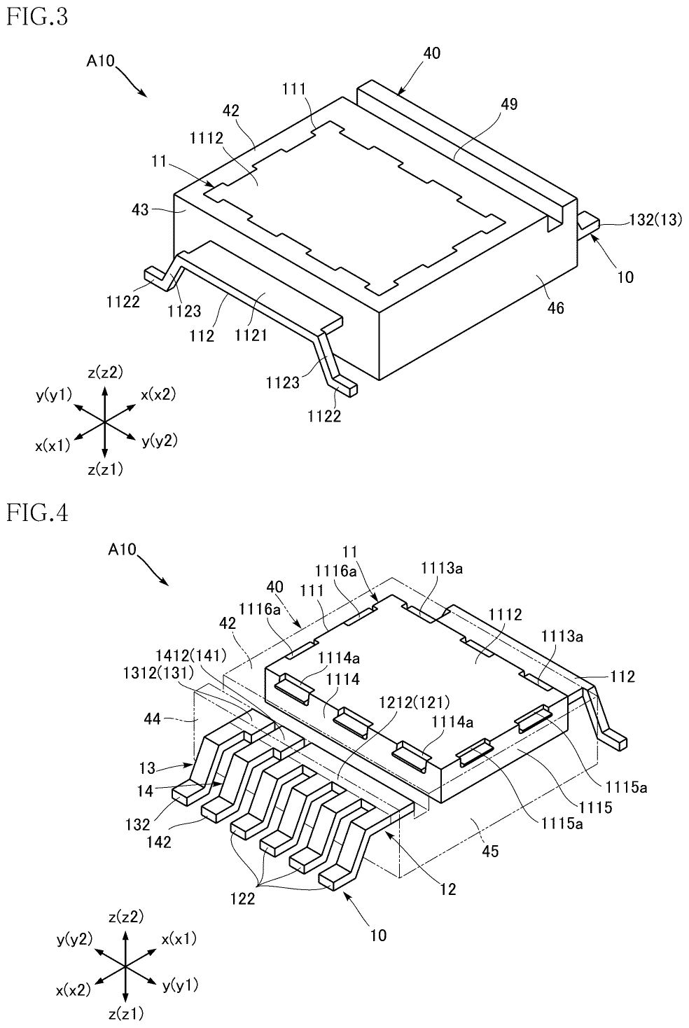

FIGS. 1 to 16 show a semiconductor device according to a first embodiment of the present disclosure. The applications of the semiconductor device A10 of the present embodiment are not particularly limited and include use in electronic devices having a power conversion circuit, such as DC-DC converters. The semiconductor device A10 includes a conductive member 10, a semiconductor element 20, connecting members 31, 32, and 33, and a sealing resin 40.

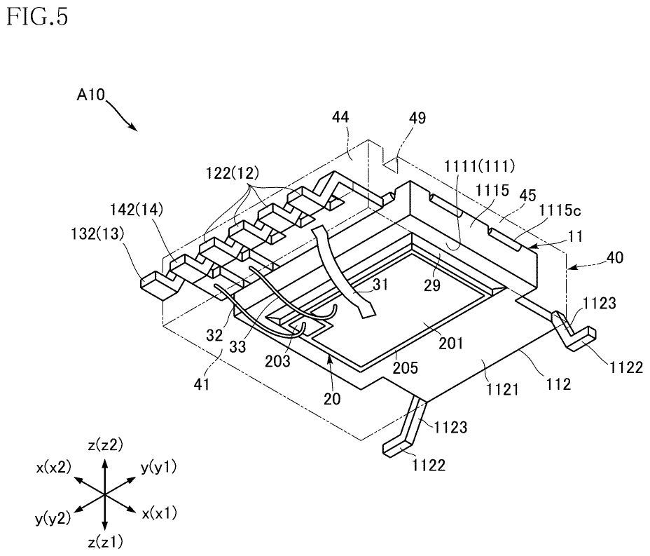

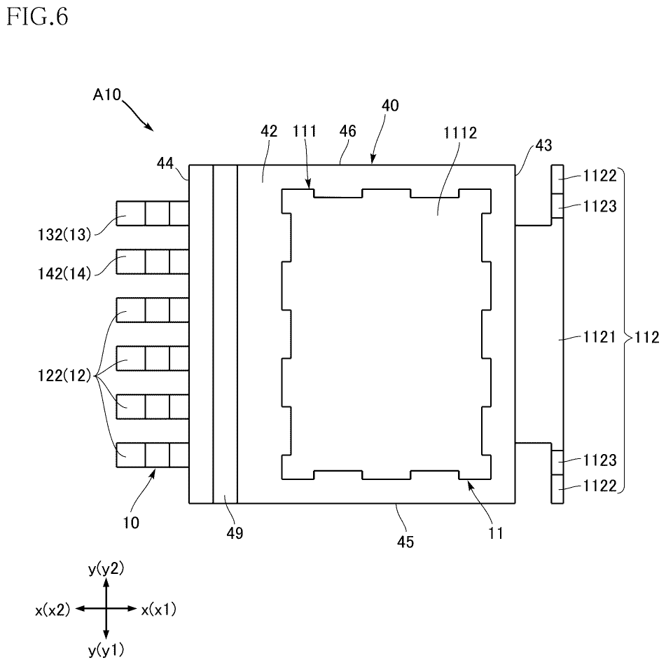

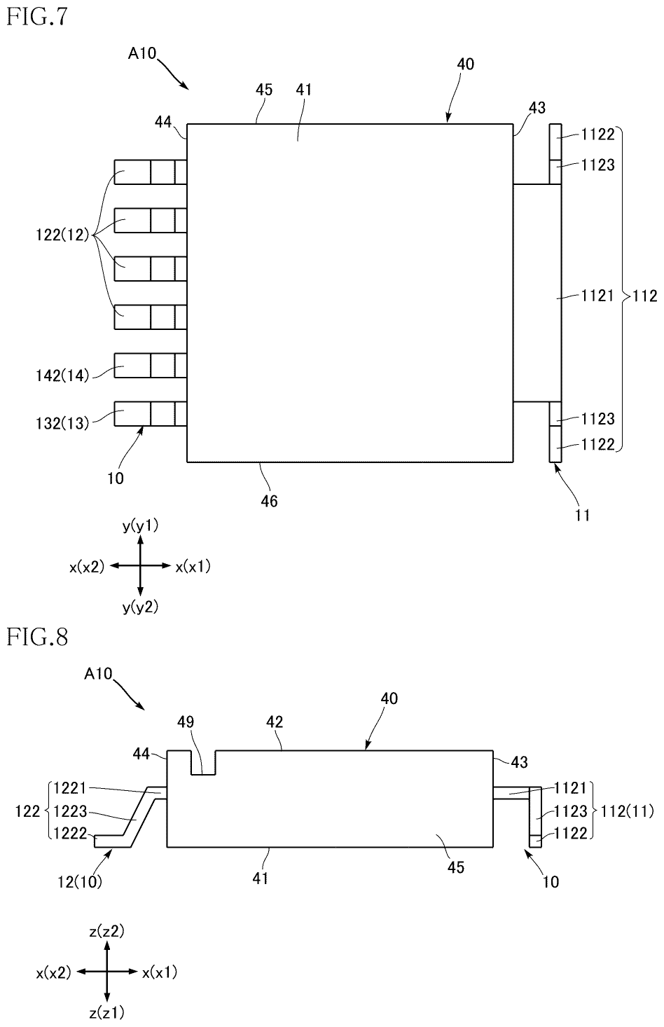

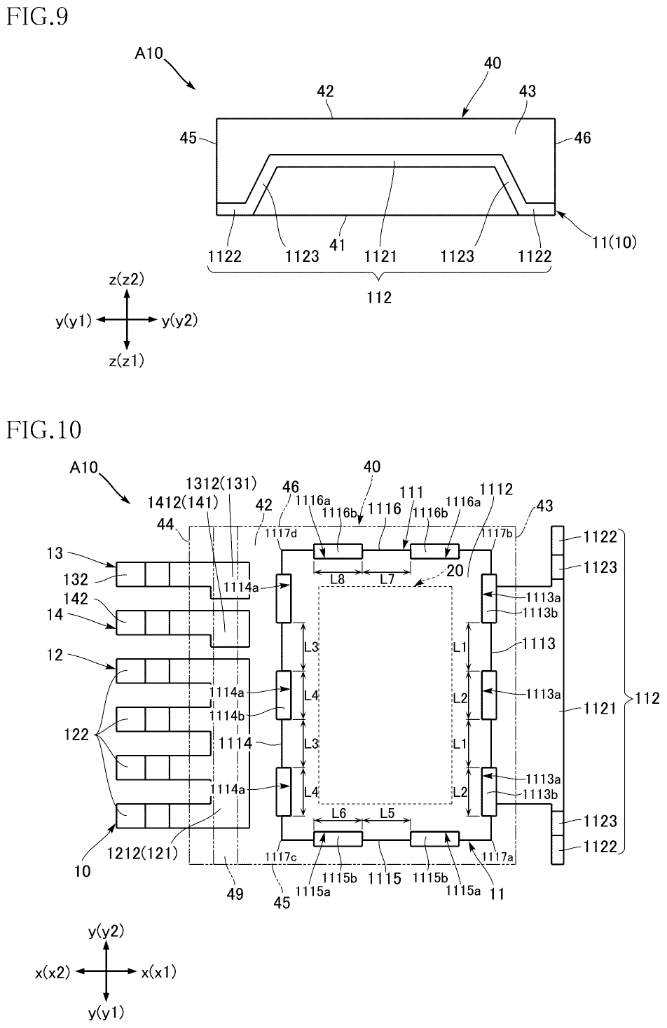

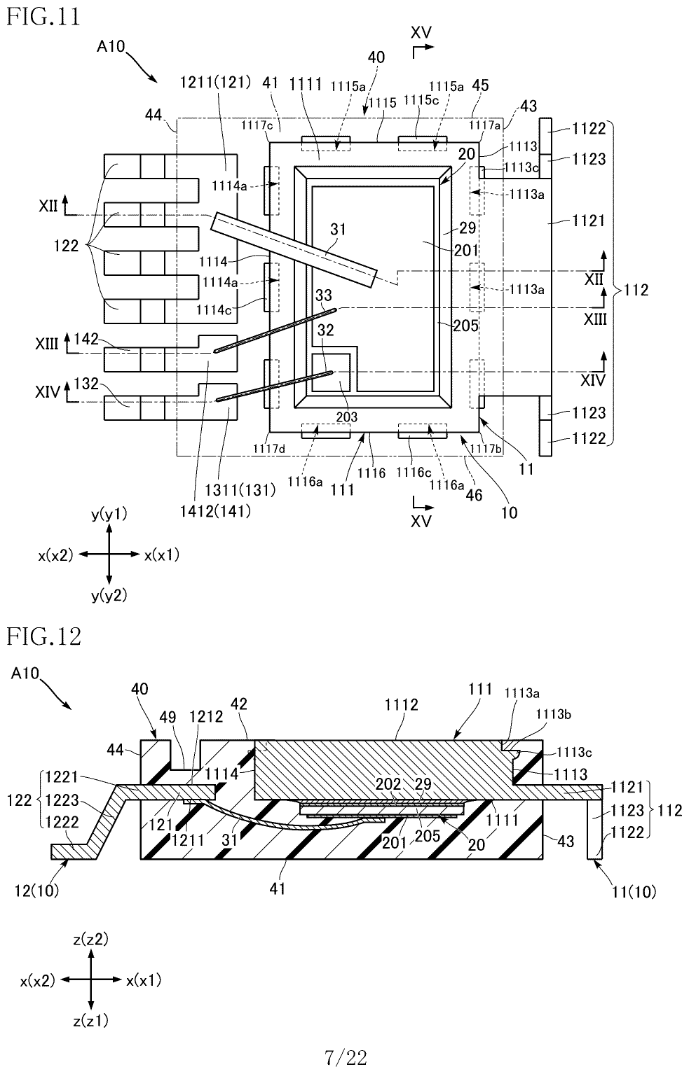

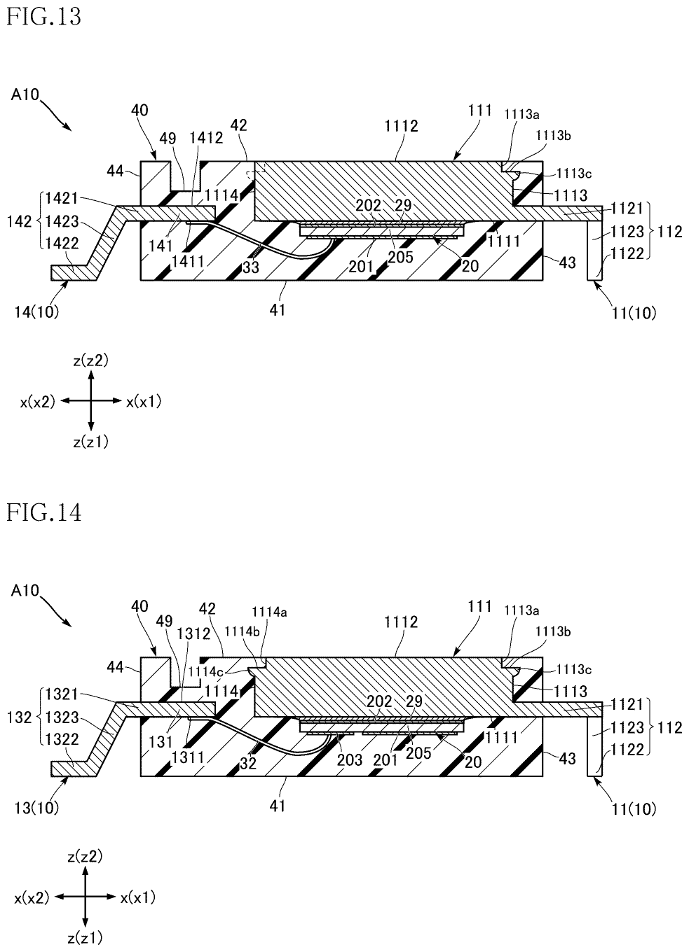

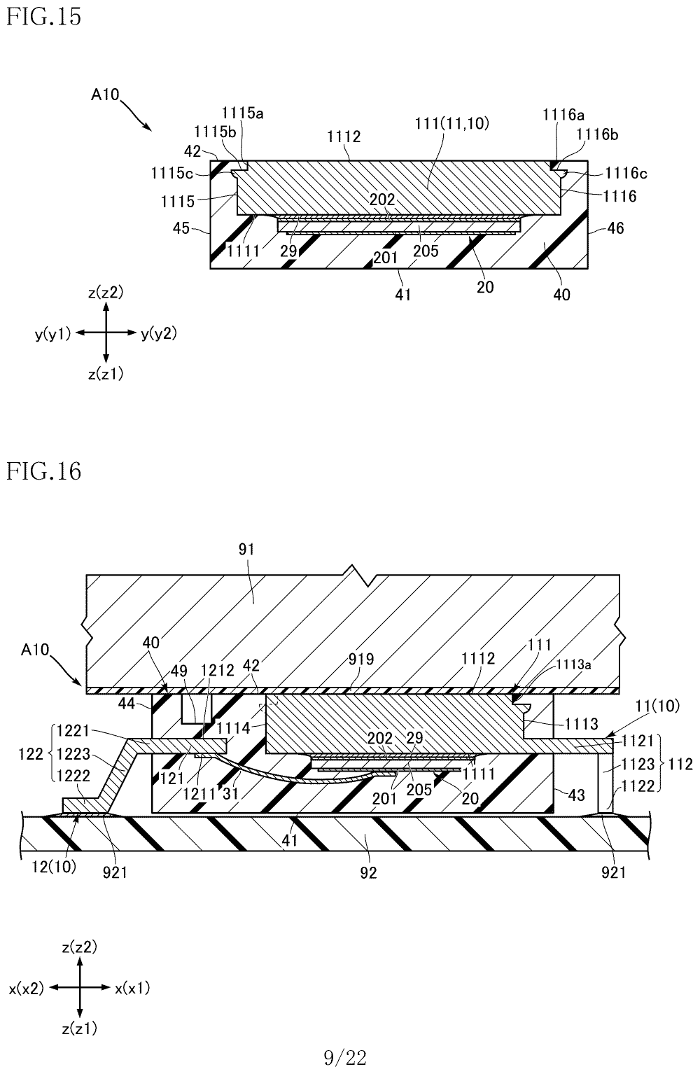

FIGS. 1 to 3 are perspective views of the semiconductor device A10. FIGS. 4 and 5 are perspective views of the main portions of the semiconductor device A10. In FIGS. 4 and 5, the outline of the sealing resin 40 is indicated by imaginary lines (dash-double-dot line). FIG. 6 is a plan view of the semiconductor device A10. FIG. 7 is a bottom view of the semiconductor device A10. FIG. 8 is a front view of the semiconductor device A10. FIG. 9 is a side view of the semiconductor device A10. FIG. 10 is a perspective view of the main portion of the semiconductor device A10. FIG. 11 is a bottom view of the main portion of the semiconductor device A10. In FIGS. 10 and 11, the outline of the sealing resin 40 is indicated by imaginary lines (dash-double-dot line). FIG. 12 is a sectional view taken along line XII-XII in FIG. 11. FIG. 13 is a sectional view taken along line XIII-XIII in FIG. 11. FIG. 14 is a sectional view taken along line XIV-XIV in FIG. 11. FIG. 15 is a sectional view taken along line XV-XV in FIG. 11. FIG. 16 is a sectional view of the semiconductor device A10 in the state of use.

In these figures, “the thickness direction z” is an example of the thickness direction of the present disclosure. The “first direction x” is an example of a direction perpendicular to the thickness direction z. The “second direction y” is the direction perpendicular to both the thickness direction z and the first direction x. In addition, one side in the thickness direction z is an example of the “first side in the thickness direction” of the present disclosure and is designated as the “z1 side in the thickness direction z”. The other side in the thickness direction z is an example of the “second side in the thickness direction” of the present disclosure and is designated as the “z2 side in the thickness direction z”. One side in the first direction x is an example of the “first side in the first direction” of the present disclosure and is designated as the “x1 side in the first direction x”. The other side in the first direction x is an example of the “second side in the first direction” of the present disclosure and is designated as the “x2 side in the first direction x.” One side in the second direction y is an example of the “first side in the second direction” of the present disclosure and is designated as the “y1 side in the second direction y”. The other side in the second direction y is an example of the “second side in the second direction” of the present disclosure and is designated as the “y2 side in the second direction y.”

The conductive member 10 forms a conduction path to the semiconductor element 20. The conductive member 10 of the present embodiment includes a first lead 11, a second lead 12, a third lead 13, and a fourth lead 14. The material of the first lead 11, the second lead 12, the third lead 13, and the fourth lead 14 is not particularly limited, and examples include copper (Cu) and a copper alloy. Appropriate portions of the first lead 11, the second lead 12, the third lead 13, and the fourth lead 14 may be plated with silver (Ag), nickel (Ni), or tin (Sn), for example.

As shown in FIGS. 1 to 15, the first lead 11 includes a die pad portion 111 and a first terminal portion 112. The die pad portion 111 has a first obverse surface 1111 and a first reverse surface 1112. The first obverse surface 1111 faces the z1 side in the thickness direction z. The first reverse surface 1112 faces the z2 side in the thickness direction z. The semiconductor element 20 is mounted on the first obverse surface 1111.

The die pad portion 111 has a first side surface 1113, a second side surface 1114, a third side surface 1115, and a fourth side surface 1116. The first side surface 1113, the second side surface 1114, the third side surface 1115, and the fourth side surface 1116 are each positioned between the first obverse surface 1111 and the first reverse surface 1112 in the thickness direction z. The first side surface 1113 and the second side surface 1114 are spaced apart from each other in the first direction x. The first side surface 1113 is positioned on the x1 side in the first direction x, facing the x1 side in the first direction x. The second side surface 1114 is positioned on the x2 side in the first direction x, facing the x2 side in the first direction x. The third side surface 1115 and the fourth side surface 1116 are spaced apart from each other in the second direction y. The third side surface 1115 is positioned on the y1 side in the second direction y, facing the y1 side in the second direction y. The fourth side surface 1116 is positioned on the y2 side in the second direction y, facing the y2 side in the second direction y.

As shown in FIG. 10, the die pad portion 111 also has a first corner 1117a, a second corner 1117b, a third corner 1117c, and a fourth corner 1117d. The first corner 1117a is where the first side surface 1113 and the third side surface 1115 meet. The second corner 1117b is where the first side surface 1113 and the fourth side surface 1116 meet. The third corner 1117c is where the second side surface 1114 and the third side surface 1115 meet. The fourth corner 1117d is where the second side surface 1114 and the fourth side surface 1116 meet.

In the present embodiment, the die pad portion 111 has a plurality of first recesses 1113a, a plurality of second recesses 1114a, a plurality of third recesses 1115a, and a plurality of fourth recesses 1116a.

Each first recess 1113a is recessed from both the first reverse surface 1112 and the first side surface 1113. The first recesses 1113a are arranged at intervals in the second direction y. In the present embodiment, the die pad portion 111 has three first recesses 1113a. The three first recesses 1113a are arranged at regular intervals in the second direction y. When the first dimension L1 is the spacing between a pair of immediately adjacent first recesses 1113a in the second direction y, and the second dimension L2 is the length of a first recess 1113a as measured in the second direction y, the first dimension L1 is one-fifth to five times the second dimension L2. In the illustrated example, the first dimension L1 is about 1.0 times the second dimension L2.

Each first recess 1113a has a first intermediate surface 1113b. The first intermediate surface 1113b is positioned between the first obverse surface 1111 and the first reverse surface 1112 in the thickness direction z and faces the z2 side in the thickness direction z (the same side as the first reverse surface 1112).

Each second recess 1114a is recessed from both the first reverse surface 1112 and the second side surface 1114. The second recesses 1114a are arranged at intervals in the second direction y. In the present embodiment, the die pad portion 111 has three second recesses 1114a. The three second recesses 1114a are arranged at regular intervals in the second direction y. When the third dimension L3 is the spacing between a pair of immediately adjacent second recesses 1114a in the second direction y, and the fourth dimension L4 is the length of a second recess 1114a as measured in the second direction y, the third dimension L3 is one-fifth to five times the fourth dimension L4. In the illustrated example, the third dimension L3 is about 1.0 times the fourth dimension L4.

Each second recess 1114a has a second intermediate surface 1114b. The second intermediate surface 1114b is positioned between the first obverse surface 1111 and the first reverse surface 1112 in the thickness direction z and faces the z2 side in the thickness direction z (the same side as the first reverse surface 1112).

Each third recess 1115a is recessed from both the first reverse surface 1112 and the third side surface 1115. The third recesses 1115a are arranged at intervals in the first direction x. In the present embodiment, the die pad portion 111 has two third recesses 1115a. When the fifth dimension L5 is the spacing between a pair of immediately adjacent third recesses 1115a in the first direction x, and the sixth dimension L6 is the length of a third recess 1115a as measured in the first direction x, the fifth dimension L5 is one-fifth to five times the sixth dimension L6. In the illustrated example, the fifth dimension L5 is about 1.0 times the sixth dimension L6.

Each third recess 1115a has a third intermediate surface 1115b. The third intermediate surface 1115b is positioned between the first obverse surface 1111 and the first reverse surface 1112 in the thickness direction z and faces the z2 side in the thickness direction z (the same side as the first reverse surface 1112).

Each fourth recess 1116a is recessed from both the first reverse surface 1112 and the fourth side surface 1116. The fourth recesses 1116a are arranged at intervals in the first direction x. In the present embodiment, the die pad portion 111 has two fourth recesses 1116a. When the seventh dimension L7 is the spacing between a pair of adjacent fourth recesses 1116a in the first direction x, and the eighth dimension L8 is the length of a fourth recess 1116a as measured in the first direction x, the seventh dimension L7 is one-fifth to five times the eighth dimension L8. In the illustrated example, the seventh dimension L7 is about 1.0 times the eighth dimension L8. Each fourth recess 1116a has a fourth intermediate surface 1116b. The fourth intermediate surface 1116b is positioned between the first obverse surface 1111 and the first reverse surface 1112 in the thickness direction z and faces the z2 side in the thickness direction z (the same side as the first reverse surface 1112).

In the illustrated example, the first recesses 1113a are positioned away from the opposite ends of the first side surface 1113 in the second direction y. Hence, each first recess 1113a is not in contact with either the first corner 1117a or the second corner 1117b. Similarly, the second recesses 1114a are positioned away from the opposite ends of the second side surface 1114 in the second direction y. Hence, each second recess 1114a is not in contact with either the third corner 1117c or the fourth corner 1117d. The third recesses 1115a are positioned away from the opposite ends of the third side surface 1115 in the first direction x. Hence, each third recess 1115a is not in contact with either the first corner 1117a or the third corner 1117c. The fourth recesses 1116a are positioned away from the opposite ends of the fourth side surface 1116 in the first direction x. Hence, each fourth recess 1116a is not in contact with either the second corner 1117b or the fourth corner 1117d.

In the illustrated example, the die pad portion 111 includes a plurality of first protrusions 1113c, a plurality of second protrusions 1114c, a plurality of third protrusions 1115c, and a plurality of fourth protrusions 1116c.

Each first protrusion 1113c is connected to one first recess 1113a. Each first protrusion 1113c protrudes from the first side surface 1113 toward the x1 side in the first direction x. Each second protrusion 1114c is connected to one second recess 1114a. Each second protrusion 1114c protrudes from the second side surface 1114 toward the x2 side in the first direction x. Each third protrusion 1115c is connected to one third recess 1115a. Each third protrusion 1115c protrudes from the third side surface 1115 toward the y1 side in the second direction y. Each fourth protrusion 1116c is connected to one fourth recess 1116a. Each fourth protrusion 1116c protrudes from the fourth side surface 1116 toward the y2 side in the second direction y.

The first to fourth recesses 1113a to 1116a and the first to fourth protrusions 1113c to 1116c with the configuration described above can be formed by pressing the first reverse surface 1112 of the die pad portion 111 toward the z1 side in the thickness direction z. The first to fourth recesses 1113a to 1116a and the first to fourth protrusions 1113c to 1116c are covered with the sealing resin 40 and thus in contact with the sealing resin 40 as will be described later.

The first terminal portion 112 includes a first section 1121, two second sections 1122, and two third sections 1123. The first section 1121 is connected to the die pad portion 111 and extends from the die pad portion 111 toward the x1 side in the first direction x. In the illustrated example, the first section 1121 is parallel (or substantially parallel) to the xy plane. In the present embodiment, the die pad portion 111 is larger than the first section 1121 in the thickness direction z. The first terminal portion 112 of the present embodiment includes a single first section 1121. The shape of the first section 1121 is not septically limited. In the illustrated example, the first section 1121 is rectangular as viewed in the thickness direction z. The first section 1121 is spaced apart from the first reverse surface 1112 in the thickness direction z. In the illustrated example, the first section 1121 is in contact with the first obverse surface 1111. The first section 1121 has a surface in flush with the first obverse surface 1111.

The two second sections 1122 are positioned on the z1 side in the thickness direction z with respect to the first section 1121. The two second sections 1122 are used for surface mounting the semiconductor device A10 to a circuit board or the like.

Each of the two third sections 1123 is present between the first section 1121 and one of the two second sections 1122. Each third section 1123 extends from the first section 1121 toward the z1 side in the thickness direction z. In the illustrated example, the third sections 1123 extend outward from the first section 1121 in the second direction y at an angle relative to the thickness direction z. The shape of the third sections 1123 is not septically limited. In the illustrated example, each third section 1123 is rectangular as viewed in the first direction x.

In the present embodiment, the two second sections 1122 extend outward in the second direction y from the respective third sections 1123. The two second sections 1122 are parallel (or substantially parallel) to the second direction y. Neither of the two second sections 1122 extends beyond the corresponding third section 1123 toward the x1 side in the first direction x. In the illustrated example, the two second sections 1122 and the two third sections 1123 are at the same (or substantially the same) positions in the first direction x.

The second lead 12 is spaced apart from the first lead 11 (the die pad portion 111) toward the x2 side in the first direction x. The second lead 12 has a pad portion 121 and a plurality of second terminal portions 122.

The pad portion 121 has a second obverse surface 1211 and a second reverse surface 1212. The second obverse surface 1211 faces the z1 side in the thickness direction z. The second reverse surface 1212 faces the z2 side in the thickness direction z. The connecting member 31 is connected to the second obverse surface 1211. The shape of the pad portion 121 is not particularly limited. In the illustrated example, the pad portion 121 has a rectangular shape elongated in the second direction y. As viewed in the thickness direction z, the pad portion 121 is smaller than the die pad portion 111. In addition, the dimension of the pad portion 121 in the thickness direction z is smaller than the die pad portion 111 and the same (or substantially same) as the first terminal portion 112. In the illustrated example, the second obverse surface 1211 is at the same (or substantially the same) position in the thickness direction z as the first obverse surface 1111 of the die pad portion 111.

The second terminal portions 122 are arranged side by side in the second direction y. Each second terminal portion 122 includes a fourth section 1221, a fifth section 1222, and a sixth section 1223.

The fourth section 1221 is connected to the pad portion 121 and extends from the pad portion 121 toward the x2 side in the first direction x. In the illustrated example, the fourth section 1221 is parallel (or substantially parallel) to the xy plane. The shape of the fourth section 1221 is not septically limited. In the illustrated example, the fourth section 1221 is rectangular as viewed in the thickness direction z.

The fifth section 1222 is positioned on the z1 side in the thickness direction z with respect to the fourth section 1221. The fifth section 1222 is used for surface mounting the semiconductor device A10 to a circuit board or the like. The fifth section 1222 is elongated shape in the first direction x.

The sixth section 1223 is present between the fourth section 1221 and the fifth section 1222. The sixth section 1223 extends from the fourth section 1221 toward the z1 side in the thickness direction z. In the illustrated example, the sixth section 1223 is inclined relative to the thickness direction z (the yz plane). The shape of the sixth section 1223 is not septically limited. In the illustrated example, the sixth section 1223 is rectangular as viewed in the first direction x.

The third lead 13 is spaced apart from the first lead 11 (the die pad portion 111) toward the x2 side in the first direction x. The third lead 13 is arranged next to the second lead 12 in the second direction y. The third lead 13 has a pad portion 131 and a third terminal portion 132.

The pad portion 131 has a third obverse surface 1311 and a third reverse surface 1312. The third obverse surface 1311 faces the z1 side in the thickness direction z. The third reverse surface 1312 faces the z2 side in the thickness direction z. The connecting member 32 is connected to the third obverse surface 1311. The shape of the pad portion 131 is not septically limited. In the illustrated example, the pad portion 131 is rectangular as viewed in the thickness direction z. Additionally, as viewed in the thickness direction z, the pad portion 131 is smaller than the pad portion 121. The dimension of the pad portion 131 in the thickness direction z is smaller than the die pad portion 111 and the same (or substantially same) as the pad portion 121. In the illustrated example, the third obverse surface 1311 is at the same (or substantially the same) position in the thickness direction z as the first obverse surface 1111 of the die pad portion 111.

The third terminal portion 132 includes a seventh section 1321, an eighth section 1322, and a ninth section 1323.

The seventh section 1321 is connected to the pad portion 131 and extends from the pad portion 131 toward the x2 side in the first direction x. In the illustrated example, the seventh section 1321 is parallel (or substantially parallel) to the xy plane. The shape of the seventh section 1321 is not septically limited. In the illustrated example, the seventh section 1321 is rectangular as viewed in the thickness direction z.

The eighth section 1322 is positioned on the z1 side in the thickness direction z with respect to the seventh section 1321. The eighth section 1322 is used for surface mounting the semiconductor device A10 to a circuit board or the like. The eighth section 1322 is elongated shape in the first direction x.

The ninth section 1323 is present between the seventh section 1321 and the eighth section 1322. The ninth section 1323 extends from the seventh section 1321 toward the z1 side in the thickness direction z. In the illustrated example, the ninth section 1323 is inclined relative to the thickness direction z (the yz plane). The shape of the ninth section 1323 is not septically limited. In the illustrated example, the ninth section 1323 is rectangular as viewed in the first direction x.

The fourth lead 14 is spaced apart from the first lead 11 (the die pad portion 111) toward the second side in the first direction x. The fourth lead 14 is present between the second lead 12 and the third lead 13 in the second direction y. The fourth lead 14 has a pad portion 141 and a fourth terminal portion 142.

The pad portion 141 has a fourth obverse surface 1411 and a fourth reverse surface 1412. The fourth obverse surface 1411 faces the z1 side in the thickness direction z. The fourth reverse surface 1412 faces the z2 side in the thickness direction z. The connecting member 33 is connected to the fourth obverse surface 1411. The shape of the pad portion 141 is not septically limited. In the illustrated example, the pad portion 141 is rectangular as viewed in the thickness direction z. As viewed in the thickness direction z, the pad portion 141 is smaller than the pad portion 121 and is as large as the pad portion 131. The dimension of the pad portion 141 in the thickness direction z is smaller than the die pad portion 111 and the same (or substantially same) as each of the pad portions 121 and 131. In the illustrated example, the fourth obverse surface 1411 is at the same (or substantially the same) position in the thickness direction z as the first obverse surface 1111 of the die pad portion 111.

The fourth terminal portion 142 has a tenth section 1421, an eleventh section 1422, and a twelfth section 1423.

The tenth section 1421 is connected to the pad portion 141 and extends from the pad portion 141 toward the x2 side in the first direction x. In the illustrated example, the tenth section 1421 is parallel (or substantially parallel) to the xy plane. The shape of the tenth section 1421 is not septically limited. In the illustrated example, the tenth section 1421 is rectangular as viewed in the thickness direction z.

The eleventh section 1422 is positioned on the z1 side in the thickness direction z with respect to the tenth section 1421. The eleventh section 1422 is used for surface mounting the semiconductor device A10 to a circuit board or the like. The eleventh section 1422 is elongated shape in the first direction x.

The twelfth section 1423 is present between the tenth section 1421 and the eleventh section 1422. The twelfth section 1423 extends from the tenth section 1421 toward the z1 side in the thickness direction z. In the illustrated example, the twelfth section 1423 is inclined relative to the thickness direction z (the yz plane). The shape of the twelfth section 1423 is not septically limited. In the illustrated example, the twelfth section 1423 is rectangular as viewed in the first direction x.

As shown in FIGS. 5 and 11 to 15, the semiconductor element 20 is mounted on the first obverse surface 1111 of the die pad portion 111. In the semiconductor device A10, the semiconductor element 20 is an n-channel, vertical MOSFET (metal-oxide-semiconductor field-effect transistor). The semiconductor element 20 is not limited to a MOSFET. The semiconductor element 20 may be a different type of transistor, such as an IGBT (insulated gate bipolar transistor). Alternatively, the semiconductor element 20 may be a diode. As viewed in the thickness direction z, the semiconductor element 20 is rectangular. As viewed in the thickness direction z, the semiconductor element 20 does not overlap any of the first recesses 1113a, the second recesses 1114a, the third recesses 1115a, and the fourth recesses 1116a. The semiconductor element 20 includes a semiconductor layer 205, a first electrode 201, a second electrode 202, and a third electrode 203.

The semiconductor layer 205 includes a compound semiconductor substrate. The primary material of the compound semiconductor substrate is silicon carbide (SIC). Alternatively, the primary material of the compound semiconductor substrate may be silicon (Si).

The first electrode 201 is disposed on the surface of the semiconductor layer 205 that faces the z1 side, which is the side that the first obverse surface 1111 of the die pad portion 111 of the first lead 11 faces in the thickness direction x. The first electrode 201 corresponds to the source electrode of the semiconductor element 20.

The second electrode 202 is disposed on the surface of the semiconductor layer 205 opposite the first electrode 201 in the thickness direction z. The second electrode 202 faces the first obverse surface 1111 of the die pad portion 111 of the first lead 11. The second electrode 202 corresponds to the drain electrode of the semiconductor element 20. In the present embodiment, the second electrode 202 is electrically bonded to the first obverse surface 1111 via a bonding layer 29. The bonding layer 29 may be a conductive bonding material, such as solder, silver (Ag) paste, or sintered silver.

The third electrode 203 is disposed on the surface of the semiconductor layer 205 that faces the z1 side in the thickness direction z, which is the same side as the first electrode 201, and is spaced apart from the first electrode 201. The third electrode 203 corresponds to the gate electrode of the semiconductor element 20. As viewed in the thickness direction z, the third electrode 203 has a smaller area than the first electrode 201.

The connecting member 31 is bonded to the first electrode 201 of the semiconductor element 20 and the second obverse surface 1211 of the pad portion 121 of the second lead 12. The material of the connecting member 31 is not particularly limited, and examples include metals, such as aluminum (Al), copper (Cu), and gold (Au). In addition, the number of connecting members 31 to be provided is not particularly limited. For example, a plurality of connecting members 31 may be provided. In the illustrated example, the connecting member 31 is contains aluminum (Al) and is a flat, belt-like component.

The connecting member 32 is bonded to the third electrode 203 of the semiconductor element 20 and the third obverse surface 1311 of the pad portion 131 of the third lead 13. In the illustrated example, the connecting member 32 contains gold (Au) and is a thread-like component that is thinner than the connecting member 31.

The connecting member 33 is bonded to the first electrode 201 of the semiconductor element 20 and the fourth obverse surface 1411 of the pad portion 141 of the fourth lead 14. In the illustrated example, the connecting member 33 contains gold (Au) and is a thread-like component that is thinner than the connecting member 31.

In the present embodiment, the first terminal portion 112 of the first lead 11 serves as the drain terminal, the second terminal portions 122 of the second lead 12 serve as the source terminals, the third terminal portion 132 of the third lead 13 serves as the gate terminal, and the fourth terminal portion 142 of the fourth lead 14 serves as the source sense terminal.

As shown in FIGS. 1 to 15, the sealing resin 40 covers the semiconductor element 20, the connecting members 31, 32, and 33, and partly covers each of the first lead 11, the second lead 12, the third lead 13, and the fourth lead 14. The sealing resin 40 is electrically insulating. The sealing resin 40 is made of a material, including a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the z1 side in the thickness direction z, which is the same side as the first obverse surface 1111 of the die pad portion 111 of the first lead 11. The second resin surface 42 faces the z2 side, which faces away from the first resin surface 41 in the thickness direction z. The first reverse surface 1112 of the die pad portion 111 of the first lead 11 is exposed from the second resin surface 42. The second resin surface 42 and the first reverse surface 1112 are flush with each other. The first reverse surface 1112 is spaced apart from the third resin surface 43 in the first direction x.

The third resin surface 43 faces the x1 side in the first direction x. The first terminal portion 112 of the first lead 11 extends such that the first section 1121 penetrates the third resin surface 43. In the present embodiment, only one first section 1121 penetrates the third resin surface 43. The first sections 1121 is spaced apart from the second resin surface 42 in the thickness direction z.

The fourth resin surface 44 faces the x2 side in the first direction x, facing away from the third resin surface 43 in the first direction x. In the present embodiment, the fourth sections 1221 of the second terminal portions 122 of the second lead 12, the seventh section 1321 of the third terminal portion 132 of the third lead 13, and the tenth section 1421 of the fourth terminal portion 142 of the fourth lead 14 penetrate the fourth resin surface 44.

The fifth resin surface 45 and the sixth resin surface 46 face away from each other in the second direction y.

As shown in FIG. 7, the first terminal portion 112 of the first lead 11 is arranged such that the ends of the two second sections 1122 in the second direction y are substantially aligned with the fifth resin surface 45 and the sixth resin surface 46 of the sealing resin 40 in the second direction y. That is, neither of the two second sections 1122 extends beyond the fifth resin surface 45 and the sixth resin surface 46 in the second direction y.

In the illustrated example, the sealing resin 40 has a groove 49. The groove 49 is recessed from the second resin surface 42 in the first direction x and extends in the second direction y. The groove 49 reaches the fifth resin surface 45 and the sixth resin surface 46. The groove 49 is positioned between the first reverse surface 1112 and the fourth resin surface 44.

With reference to FIGS. 16 and 17, the following describes a usage example of the semiconductor device A10.

FIG. 16 shows the semiconductor device A10 in the state of use. In this usage example, the semiconductor device A10 is surface mounted on a circuit board 92. That is, the semiconductor device A10 is mounted by electrically bonding the second sections 1122 of the first terminal portion 112, the fifth section 1222 of each second terminal portion 122, the eighth section 1322 of the third terminal portion 132, and the eleventh section 1422 of the fourth terminal portion 142 to a wiring pattern (not shown) of the circuit board 92 using solder 921, for example. In addition, a heatsink 91 is disposed to face the first reverse surface 1112 of the die pad portion 111. In the illustrated example, a sheet material 919 is disposed between the first reverse surface 1112 and the heatsink 91. The sheet material 919 is an insulating sheet, for example.

FIG. 17 is a schematic view of a vehicle B1 provided with the semiconductor device A10. The vehicle B1 is an electric vehicle (EV), for example. As shown in FIG. 17, the vehicle B1 includes an AC-DC converter 81, a power receiver 82, a storage battery 83, and a drive system 84. The semiconductor device A10 forms part of the AC-DC converter 81. When the vehicle B1 receives AC power from a charging station 80, which may be an outdoor AC source, the AC-DC converter 81 converts it to high-voltage DC power. The AC-DC converter 81 supplies the resulting high-voltage DC power to the storage battery 83. The power receiver 82 utilizes a non-contact charging system to charge the storage battery 83 via electromagnetic induction from a non-contact charger (not shown), which may be installed in a parking lot, for example. The power stored in the storage battery 83 is supplied to the drive system 84, which consists of an inverter, an AC motor, and a transmission. The drive system 84 drives the vehicle B1. The AC-DC converter 81 is an example of the “power conversion device” of the present disclosure.

The following describes the operation of the semiconductor device A10.

In the semiconductor device A10, the die pad portion 111, which supports the semiconductor element 20, has the first reverse surface 1112 facing the z2 side in the thickness direction z and the first side surface 1113 facing the x1 side in the first direction x. The first reverse surface 1112 is exposed from the sealing resin 40. The die pad portion 111 also has the first recesses 1113a. Each first recess 1113a is recessed from both the first reverse surface 1112 and the first side surface 1113. The first recesses 1113a are arranged at intervals in the second direction y. Providing the die pad portion 111 with the first recesses 1113a described above efficiently increases the contact area between the die pad portion 111, which supports the semiconductor element 20, and the sealing resin 40, thereby improving adhesion between the die pad portion 111 and the sealing resin 40.

In the present embodiment, the first dimension L1 (the spacing between a pair of immediately adjacent first recesses 1113a in the second direction y) is one-fifth to five times the second dimension L2 (the length of a first recess 1113a as measured in the second direction y). This configuration ensures that even if peeling of the sealing resin 40 occurs locally at one first recess 1113a, the peeling of the sealing resin 40 will not propagate to other first recesses 1113a, which are distributed along the second direction y.

The die pad portion 111 also includes the second recesses 1114a, the third recesses 1115a, and the fourth recesses 1116a. Each second recess 1114a is recessed from both the first reverse surface 1112 and the second side surface 1114. The second recesses 1114a are arranged at intervals in the second direction y. Each third recess 1115a is recessed from both the first reverse surface 1112 and the third side surface 1115. The third recesses 1115a are arranged at intervals in the first direction x. Each fourth recess 1116a is recessed from both the first reverse surface 1112 and the fourth side surface 1116. The fourth recesses 1116a are arranged at intervals in the first direction x. Providing the die pad portion 111 with the second recesses 1114a, the third recesses 1115a, and the fourth recesses 1116a described above efficiently increases the contact area between the die pad portion 111, which supports the semiconductor element 20, and the sealing resin 40, thereby improving adhesion between the die pad portion 111 and the sealing resin 40.

In the present embodiment, the third dimension L3 (the spacing between a pair of immediately adjacent second recesses 1114a in the second direction y) is one-fifth to five times the fourth dimension L4 (the length of a second recess 1114a as measured in the second direction y). This configuration ensures that even if peeling of the sealing resin 40 occurs locally at one second recess 1114a, the peeling of the sealing resin 40 will not propagate to other second recesses 1114a, which are distributed along the second direction y. Similarly, the fifth dimension L5 (the spacing between a pair of immediately adjacent third recesses 1115a in the first direction x) is one-fifth to five times the sixth dimension L6 (the length of a third recess 1115a as measured in the first direction x). Similarly, the seventh dimension L7 (the spacing between a pair of immediately adjacent fourth recesses 1116a in the first direction x) is one-fifth to five times the eighth dimension L8 (the length of a fourth recess 1116a as measured in the first direction x). This configuration ensures that even if peeling of the sealing resin 40 occurs locally at one third recess 1115a or one fourth recess 1116a, the peeling of the sealing resin 40 will not propagate to other third recesses 1115a or other fourth recesses 116a.

Each first recess 1113a is not in contact with either the first corner 1117a or the second corner 1117b. Similarly, each second recess 1114a is not in contact with either the third corner 1117c or the fourth corner 1117d. Each third recess 1115a is not in contact with either the first corner 1117a or the third corner 1117c. Similarly, each fourth recess 1116a is not in contact with either the second corner 1117b or the fourth corner 1117d. This configuration prevents peeling of the sealing resin 40 at the four corners (the first to fourth corners 1117a to 1117d) of the die pad portion 111. This is desirable for improving adhesion between the die pad portion 111 and the sealing resin 40.

The semiconductor element 20 does not overlap any of the first recesses 1113a, the second recesses 1114a, the third recesses 1115a, and the fourth recesses 1116a as viewed in the thickness direction z. The respective first to fourth recesses 1113a to 1116a can be formed by pressing. However, the flatness of the first obverse surface 1111, which is opposite the pressed surface, may be reduced at the locations corresponding to the first to fourth recesses 1113a to 1116a as viewed in the thickness direction z. In the present embodiment, the semiconductor element 20 is positioned so as not overlap any of the respective first to fourth recesses 1113a, thereby ensuring a good bond to the first obverse surface 1111.

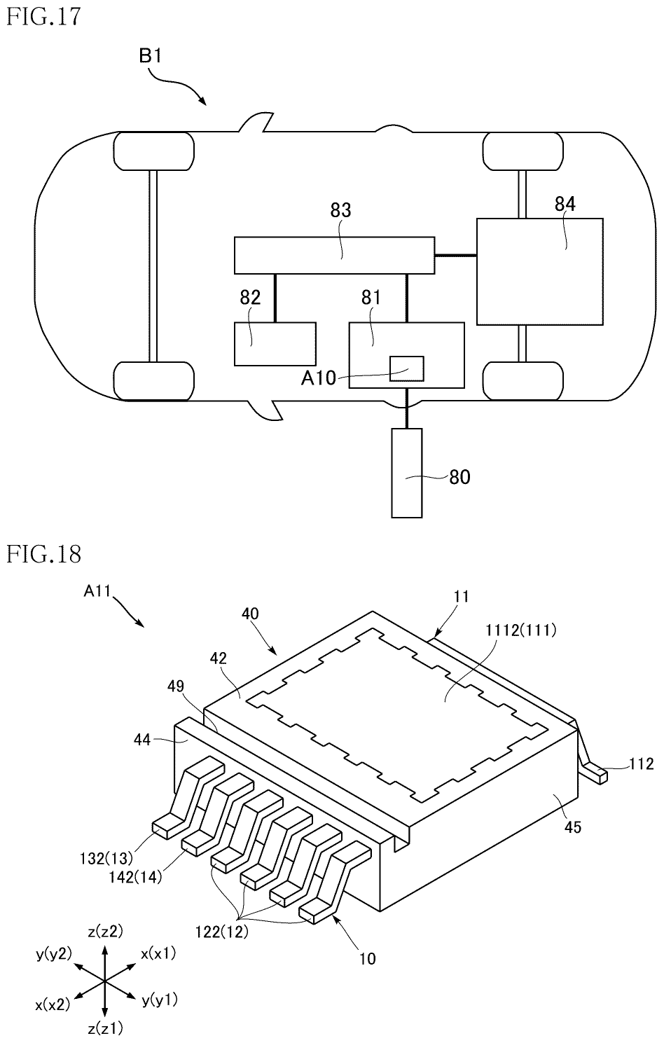

FIGS. 18 to 36 show variations and other embodiments of semiconductor devices according to the present disclosure. In these figures, elements that are identical or similar to those of the embodiment described above are indicated by the same reference numerals, and redundant descriptions are omitted. Also, configurations of elements and components in the embodiments and variations may be combined in any manner, provided that no technical inconsistencies arise. First Variation:

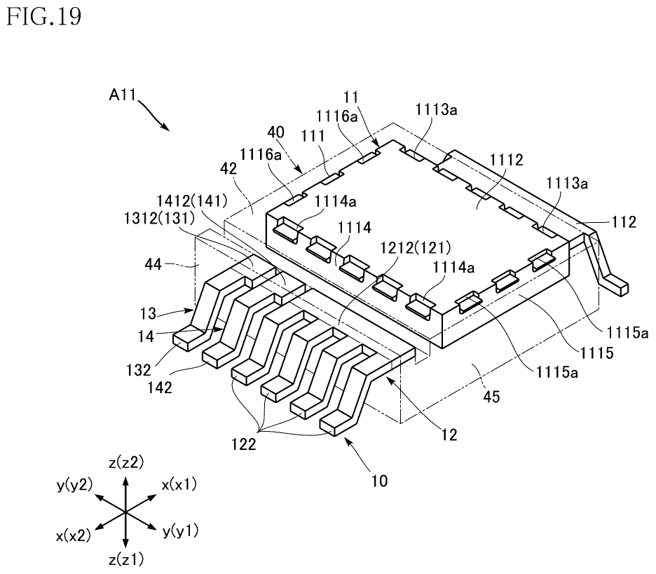

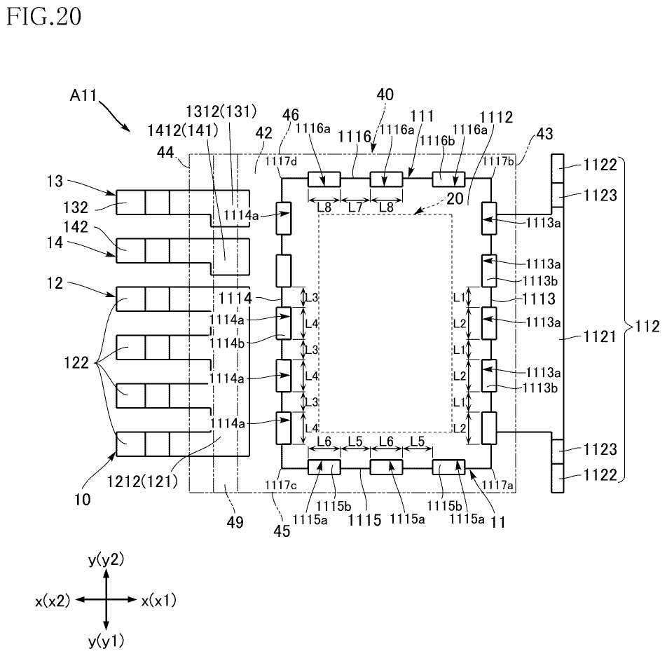

FIGS. 18 to 20 show a first variation of the semiconductor device A10. FIG. 18 is a perspective view of a semiconductor device A11 according to the first variation. FIG. 19 is a perspective view of the main portion of the semiconductor device A11. FIG. 20 is a plan view of the main portion of the semiconductor device A11. In FIGS. 19 and 20, the outline of the sealing resin 40 is indicated by an imaginary line (dash-double-dot line). The semiconductor device A11 of this variation differs from the semiconductor device A10 in the arrangement of the first recesses 1113a, the second recesses 1114a, the third recesses 1115a, and the fourth recesses 1116a in the die pad portion 111.

The die pad portion 111 of the semiconductor device A11 is formed with a greater number of respective recesses, namely the first recesses 1113a, the second recesses 1114a, the third recesses 1115a, and the fourth recesses 1116a, compared to the die pad portion of the semiconductor device A10. Specifically, the die pad portion 111 has five first recesses 1113a, five second recesses 1114a, three third recesses 1115a, and three fourth recesses 1116a.

The five first recesses 1113a are arranged at regular intervals in the second direction y. When the first dimension L1 is the spacing between a pair of immediately adjacent first recesses 1113a in the second direction y, and the second dimension L2 is the length of a first recess 1113a as measured in the second direction y, the first dimension L1 is one-fifth to five times the second dimension L2. In the illustrated example, the first dimension L1 is about 0.63 times the second dimension L2. The five second recesses 1114a are arranged at regular intervals in the second direction y. When the third dimension L3 is the spacing between a pair of immediately adjacent second recesses 1114a in the second direction y, and the fourth dimension L4 is the length of a second recess 1114a as measured in the second direction y, the third dimension L3 is one-fifth to five times the fourth dimension L4. In the illustrated example, the third dimension L3 is about 0.63 times the fourth dimension L4. The three third recesses 1115a are arranged at regular intervals in the first direction x. When the fifth dimension L5 is the spacing between a pair of immediately adjacent third recesses 1115a in the first direction x, and the sixth dimension L6 is the length of a third recess 1115a as measured in the first direction x, the fifth dimension L5 is one-fifth to five times the sixth dimension L6. In the illustrated example, the fifth dimension L5 is about 0.93 times the sixth dimension L6. The three fourth recesses 1116a are arranged at regular intervals in the first direction x. When the seventh dimension L7 is the spacing between a pair of adjacent fourth recesses 1116a in the first direction x, and the eighth dimension L8 is the length of a fourth recess 1116a as measured in the first direction x, the seventh dimension L7 is one-fifth to five times the eighth dimension L8. In the illustrated example, the seventh dimension L7 is about 0.93 times the eighth dimension L8.

In the semiconductor device A11, the die pad portion 111, which supports the semiconductor element 20, has the first recesses 1113a. Each first recess 1113a is recessed from both the first reverse surface 1112 and the first side surface 1113. The first recesses 1113a are arranged at intervals in the second direction y. Providing the die pad portion 111 with the first recesses 1113a described above efficiently increases the contact area between the die pad portion 111, which supports the semiconductor element 20, and the sealing resin 40, thereby improving adhesion between the die pad portion 111 and the sealing resin 40.

In this variation, the first dimension L1 (the spacing between a pair of immediately adjacent first recesses 1113a in the second direction y) is one-fifth to five times the second dimension L2 (the length of a first recess 1113a as measured in the second direction y). This configuration ensures that even if peeling of the sealing resin 40 occurs locally at one first recess 1113a, the peeling of the sealing resin 40 will not propagate to other first recesses 1113a, which are distributed along the second direction y. Additionally, the semiconductor device A11 achieves the same advantages as the semiconductor device A10 of the above-described embodiment.

The die pad portion 111 of the semiconductor device A11 has a greater number of respective recesses, namely the first recesses 1113a, the second recesses 1114a, the third recesses 1115a, and the fourth recesses 1116a, compared to the die pad portion of the semiconductor device A10. This configuration further increases the contact area between the die pad portion 111 and the sealing resin 40. This is desirable for improving adhesion between the die pad portion 111 and the sealing resin 40.

### Second Variation:

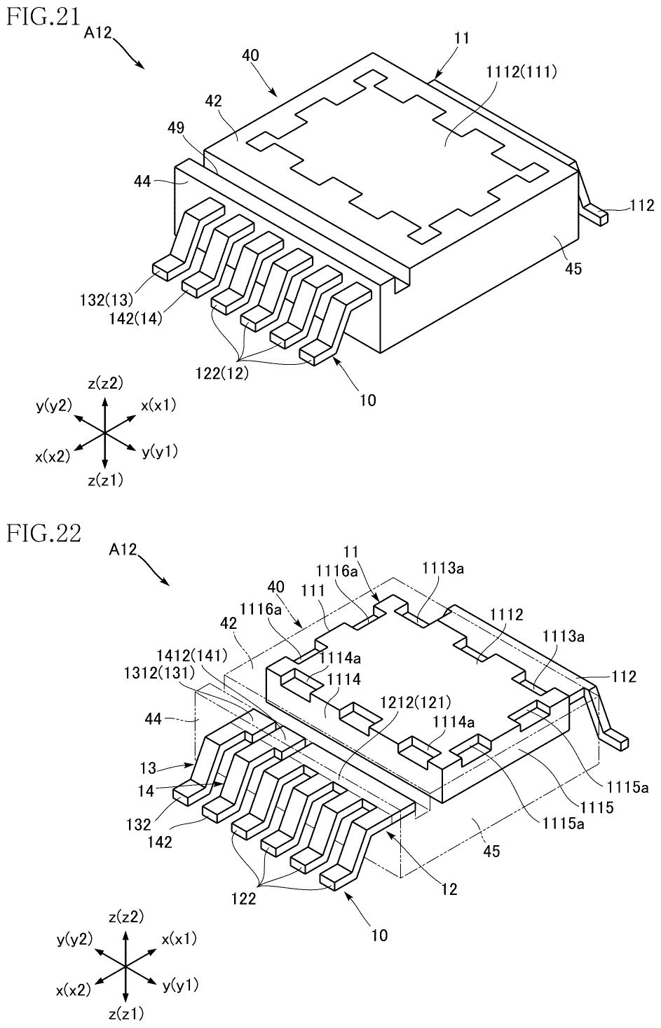

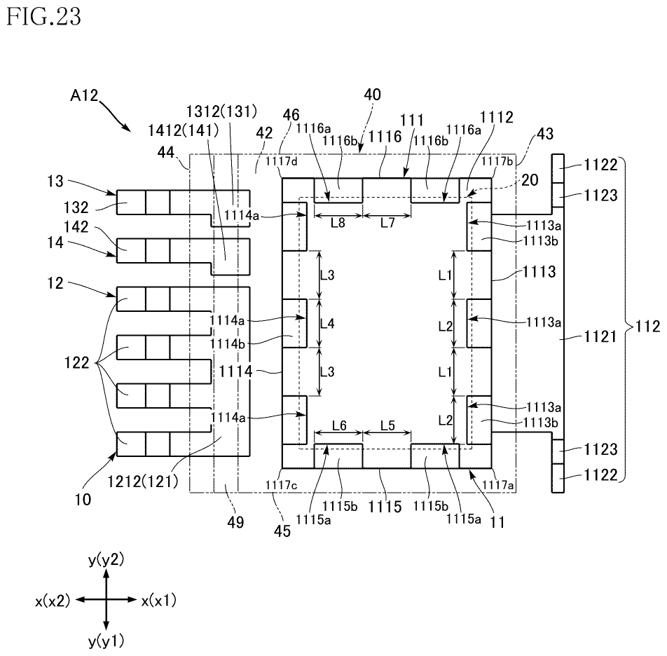

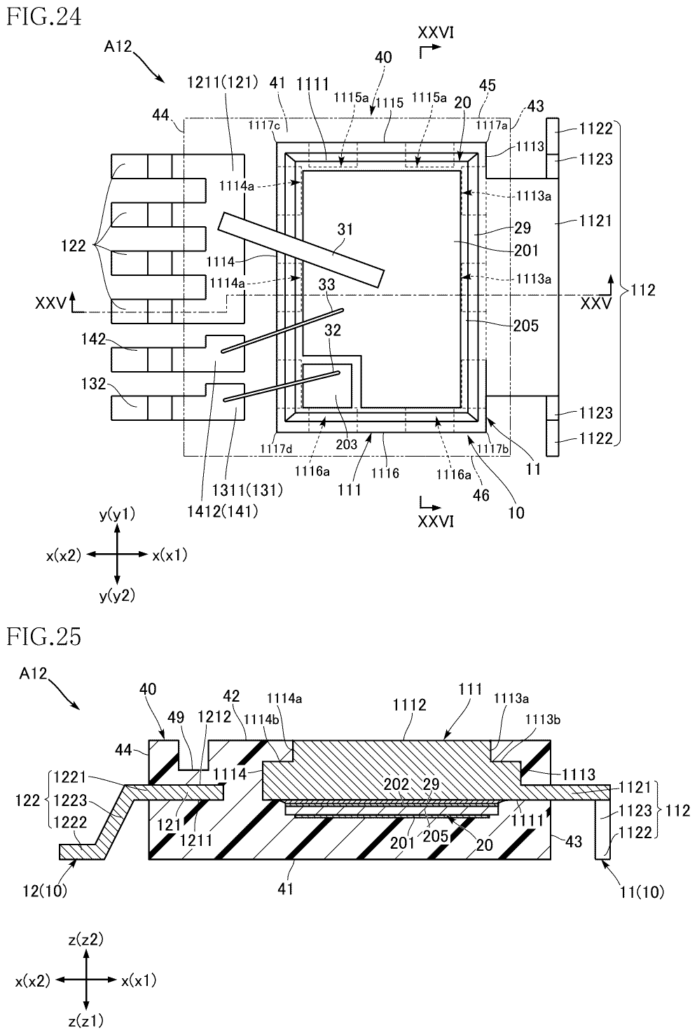

FIGS. 21 to 26 show a second variation of the semiconductor device A10. FIG. 21 is a perspective view of a semiconductor device A12 according to the second variation. FIG. 22 is a perspective view of the main portion of the semiconductor device A12. FIG. 23 is a plan view of the main portion of the semiconductor device A12. FIG. 24 is a bottom view of the main portion of the semiconductor device A12. In FIGS. 22 to 24, the outline of the sealing resin 40 is indicated by an imaginary line (dash-double-dot line). FIG. 25 is a sectional view taken along line XXV-XXV in FIG. 24. FIG. 26 is a sectional view taken along line XXVI-XXVI in FIG. 24. The semiconductor device A12 of this variation differs from the semiconductor device A10 in the configuration of the first recesses 1113a, second recesses 1114a, third recesses 1115a, and fourth recesses 1116a in the die pad portion 111, as well as in the and arrangement of the semiconductor element 20.

The first recesses 1113a of the semiconductor device A12 are longer in the thickness direction z (the distance between the first reverse surface 1112 and the first intermediate surface 1113b in the thickness direction z) than those of the semiconductor device A10. Similarly, the second recesses 1114a, the third recesses 1115a, and the fourth recesses 1116a are longer in the thickness direction z than the corresponding recesses of the semiconductor device A10. The first recesses 1113a of the semiconductor device A12 are also longer in the first direction x than those of the semiconductor device A10. Similarly, the second recesses 1114a are also longer in the first direction x than those of the semiconductor device A10, and the third recesses 1115a and the fourth recesses 1116a are longer in the second direction y than the corresponding recesses of the semiconductor device A10. Regarding the first to eighth dimensions L1 to L8 described above for the semiconductor device A10, the corresponding dimensions of the semiconductor device A12 are the same (or about the same).

Unlike the semiconductor device A10 of the embodiment described above, the die pad portion 111 of the semiconductor device A12 lacks the first protrusions 1113c, the second protrusions 1114c, the third protrusions 1115c, and the fourth protrusions 1116c. In this variation, the first recesses 1113a, the second recesses 1114a, the third recesses 1115a, and the fourth recesses 1116a are formed by chemical processing, such as etching.

The semiconductor element 20 of the semiconductor device A12 is larger in plan view (as viewed in the thickness direction z) than that of the semiconductor device A10. As viewed in the thickness direction z, the semiconductor element 20 partly overlaps each of the first recesses 1113a, second recesses 1114a, third recesses 1115a, and fourth recesses 1116a.

In the semiconductor device A12, the die pad portion 111, which supports the semiconductor element 20, has the first recesses 1113a. Each first recess 1113a is recessed from both the first reverse surface 1112 and the first side surface 1113. The first recesses 1113a are arranged at intervals in the second direction y. Providing the die pad portion 111 with the first recesses 1113a described above efficiently increases the contact area between the die pad portion 111, which supports the semiconductor element 20, and the sealing resin 40, thereby improving adhesion between the die pad portion 111 and the sealing resin 40.

In this variation, the first dimension L1 (the spacing between a pair of immediately adjacent first recesses 1113a in the second direction y) is one-fifth to five times the second dimension L2 (the length of a first recess 1113a as measured in the second direction y). This configuration ensures that even if peeling of the sealing resin 40 occurs locally at one first recess 1113a, the peeling of the sealing resin 40 will not propagate to other first recesses 1113a, which are distributed along the second direction y. Additionally, the semiconductor device A12 achieves the same advantages as the semiconductor device A10 of the above-described embodiment within the scope of configurations similar to semiconductor device A10.

### Second Embodiment

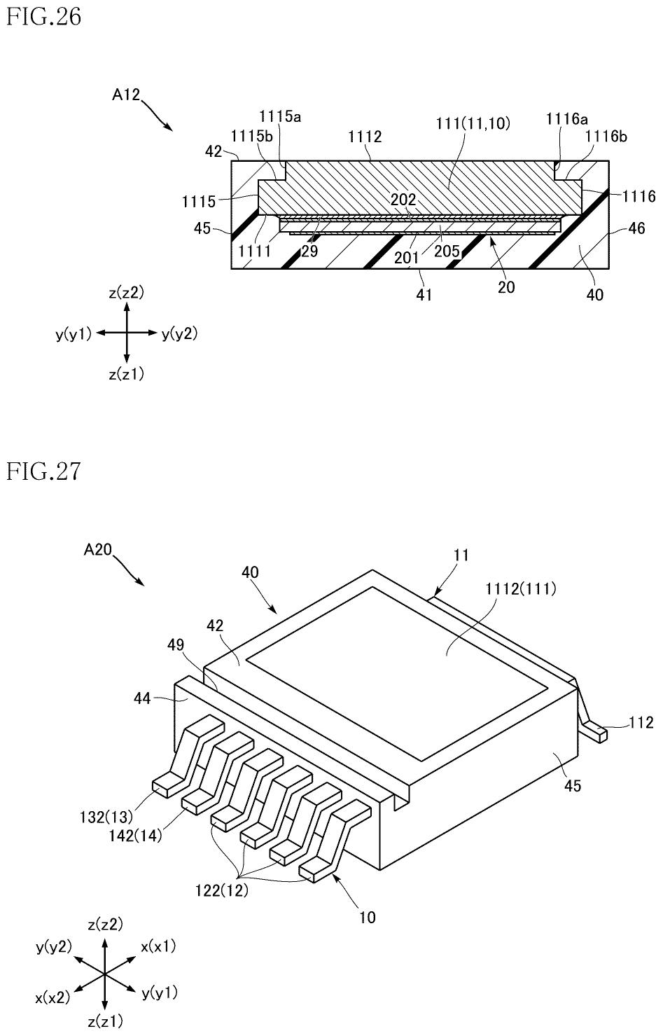

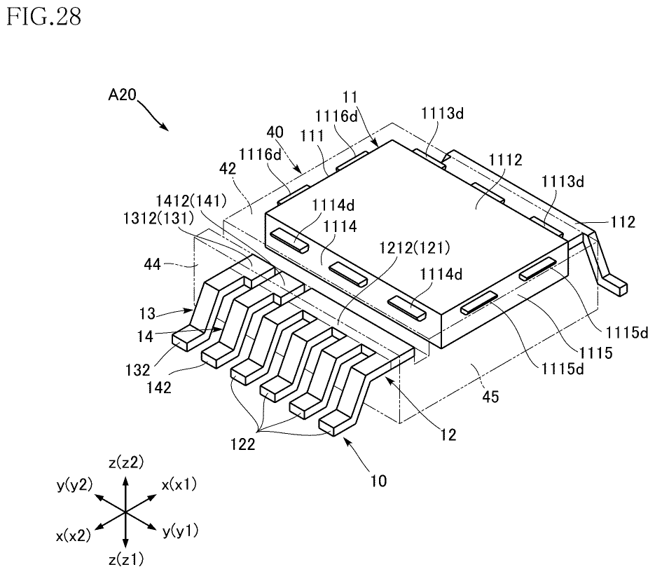

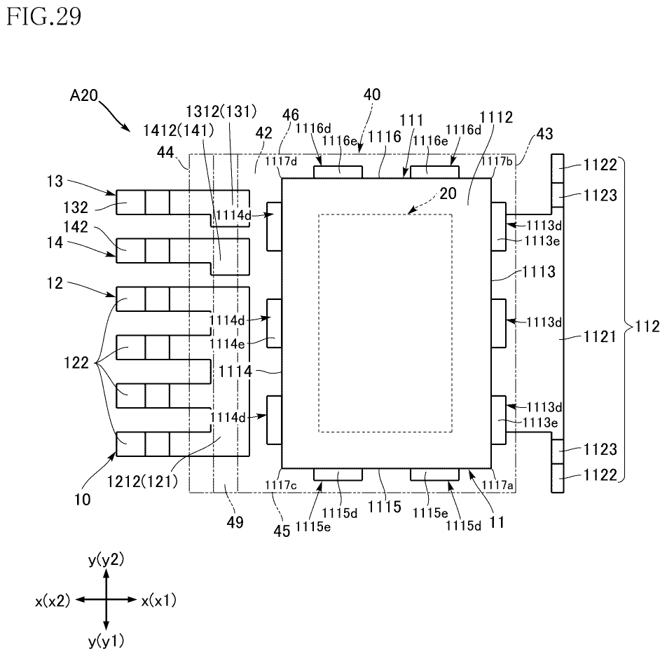

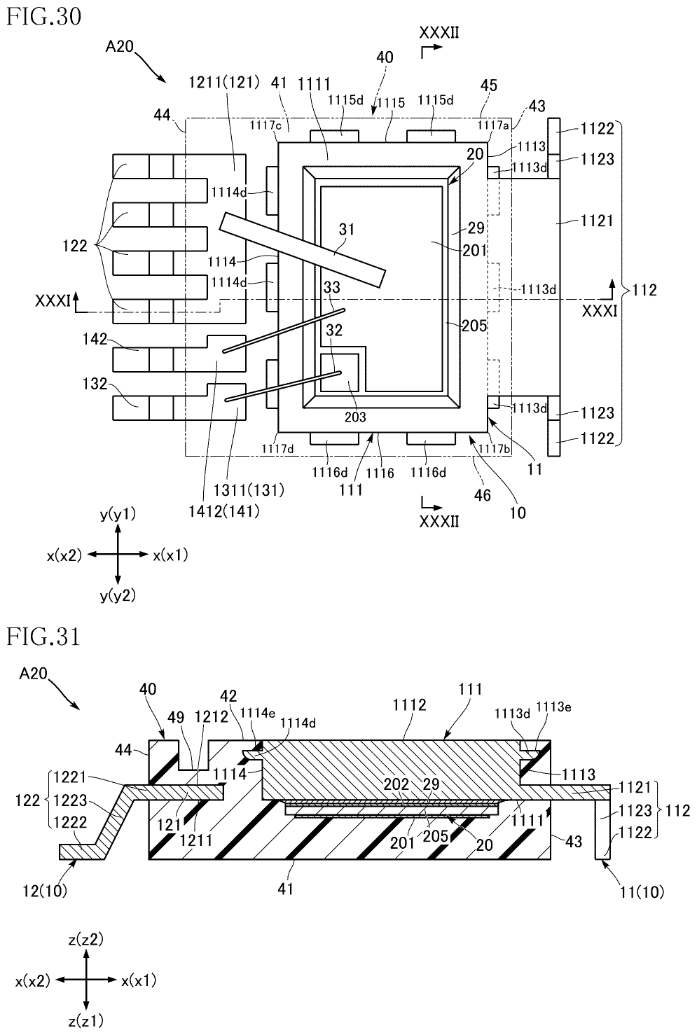

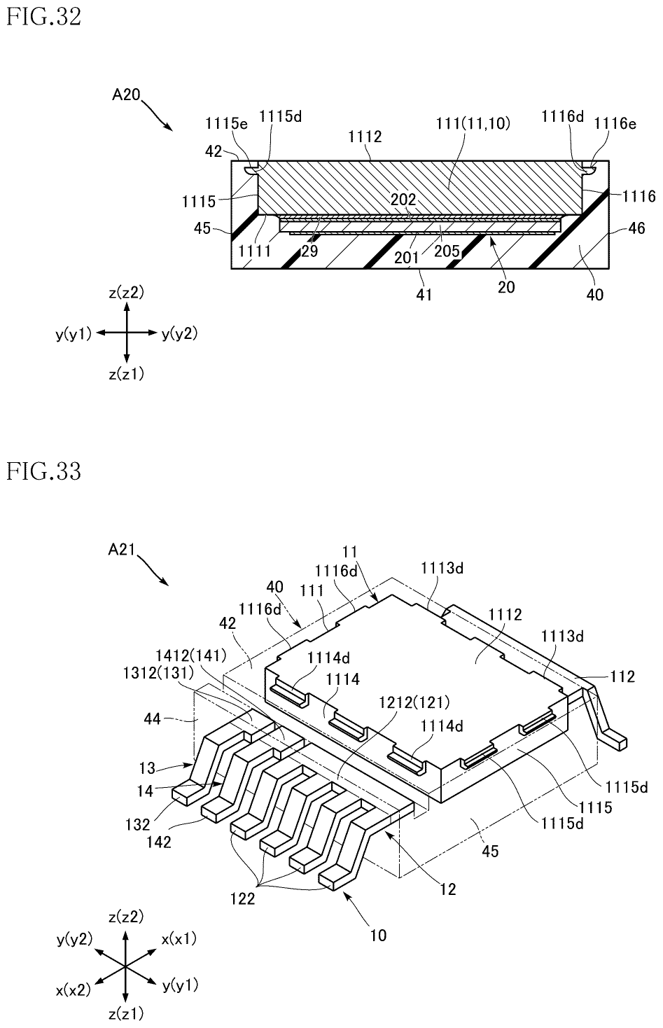

FIGS. 27 to 32 show a semiconductor device according to a second embodiment of the present disclosure. FIG. 27 is a perspective view of a semiconductor device A20 according to the second embodiment of the present disclosure. FIG. 28 is a perspective view of the main portion of the semiconductor device A20. FIG. 29 is a plan view of the main portion of the semiconductor device A20. FIG. 30 is a bottom view of the main portion of the semiconductor device A20. In FIGS. 28 to 30, the outline of the sealing resin 40 is indicated by an imaginary line (dash-double-dot line). FIG. 31 is a sectional view taken along line XXXI-XXXI in FIG. 30. FIG. 32 is a sectional view taken along line XXXII-XXXII in FIG. 30. The semiconductor device A20 of the present embodiment has a die pad portion 111 with a configuration different from that of the semiconductor device A10.

The die pad portion 111 of the semiconductor device A20 has a plurality of fifth protrusions 1113d, a plurality of sixth protrusions 1114d, a plurality of seventh protrusions 1115d, and a plurality of eighth protrusions 1116d. The die pad portion 111 of the semiconductor device A20, however, lacks the first recesses 1113a, second recesses 1114a, third recesses 1115a, and fourth recesses 1116a, which are present in the embodiment described above.

Each fifth protrusion 1113d protrudes from the first side surface 1113 toward the x1 side in the first direction x. Each fifth protrusion 1113d is positioned proximate to the end of the first side surface 1113 on the z2 side in the thickness direction z. The fifth protrusions 1113d are arranged at intervals in the second direction y. In the present embodiment, the die pad portion 111 has three fifth protrusions 1113d. The three fifth protrusions 1113d are arranged at regular intervals in the second direction y.

Each fifth protrusion 1113d has a fifth intermediate surface 1113e. The fifth intermediate surface 1113e is positioned between the first obverse surface 1111 and the first reverse surface 1112 in the thickness direction z and faces the z2 side in the thickness direction z (the same side as the first reverse surface 1112).

Each sixth protrusion 1114d protrudes from the second side surface 1114 toward the x2 side in the first direction x. Each sixth protrusion 1114d is positioned proximate to the end of the second side surface 1114 on the z2 side in the thickness direction z. The sixth protrusions 1114d are arranged at intervals in the second direction y. In the present embodiment, the die pad portion 111 has three sixth protrusions 1114d. The three sixth protrusions 1114d are arranged at regular intervals in the second direction y.

Each sixth protrusion 1114d has a sixth intermediate surface 1114e. The sixth intermediate surface 1114e is positioned between the first obverse surface 1111 and the first reverse surface 1112 in the thickness direction z and faces the z2 side in the thickness direction z (the same side as the first reverse surface 1112).

Each seventh protrusion 1115d protrudes from the third side surface 1115 toward the y1 side in the second direction y. Each seventh protrusion 1115d is positioned proximate to the end of the third side surface 1115 on the z2 side in the thickness direction z. The seventh protrusions 1115d are arranged at intervals in the first direction x. In the present embodiment, the die pad portion 111 has two seventh protrusions 1115d.

Each seventh protrusion 1115d has a seventh intermediate surface 1115e. The seventh intermediate surface 1115e is positioned between the first obverse surface 1111 and the first reverse surface 1112 in the thickness direction z and faces the z2 side in the thickness direction z (the same side as the first reverse surface 1112).

Each eighth protrusion 1116d protrudes from the fourth side surface 1116 toward the y2 side in the second direction y. Each eighth protrusion 1116d is positioned proximate to the end of the fourth side surface 1116 on the z2 side in the thickness direction z. The eighth protrusions 1116d are arranged at intervals in the first direction x. In the present embodiment, the die pad portion 111 has two eighth protrusions 1116d.

Each eighth protrusion 1116d has an eighth intermediate surface 1116e. The eighth intermediate surface 1116e is positioned between the first obverse surface 1111 and the first reverse surface 1112 in the thickness direction z and faces the z2 side in the thickness direction z (the same side as the first reverse surface 1112).

In the illustrated example, the fifth protrusions 1113d are positioned away from the opposite ends of the first side surface 1113 in the second direction y. Hence, each fifth protrusion 1113d is not in contact with either the first corner 1117a or the second corner 1117b. Also, the sixth protrusions 1114d are positioned away from the opposite ends of the second side surface 1114 in the second direction y. Hence, each sixth protrusion 1114d is not in contact with either the third corner 1117c or the fourth corner 1117d. The seventh protrusions 1115d are positioned away from the opposite ends of the third side surface 1115 in the first direction x. Hence, each seventh protrusion 1115d is not in contact with either the first corner 1117a or the third corner 1117c. The eighth protrusions 1116d are positioned away from the opposite ends of the fourth side surface 1116 in the first direction x. Hence, each eighth protrusion 1116d is not in contact with either the second corner 1117b or the fourth corner 1117d.

The fifth to eighth protrusions 1113d to 1116d with the configuration described above can be formed by pressing the first reverse surface 1112 of the die pad portion 111 toward the z1 side in the thickness direction z. Before the pressing, the die pad portion 111 is provided with a plurality of projections that each correspond to the fifth to eighth protrusions 1113d to 1116d. Each projection is connected to the first reverse surface 1112 and projects outward from one of the first to fourth side surfaces 1113 to 1116. In the present embodiment, the projections are pressed along the edges of the first reverse surface 1112. This process forms the fifth to eighth protrusions 1113d to 1116d having their corresponding fifth to eighth intermediate surfaces 1113e to 1116e. The respective fifth to eighth protrusions 1113d to 1116d are all covered with the sealing resin 40 and thus in contact with the sealing resin 40.

In the semiconductor device A20, the die pad portion 111, which supports the semiconductor element 20, has the plurality of fifth protrusions 1113d. Each fifth protrusion 1113d protrudes from the first side surface 1113 toward the x1 side in the first direction x. The fifth protrusions 1113d are arranged at intervals in the second direction y. Providing the die pad portion 111 with the fifth protrusions 1113d described above efficiently increases the contact area between the die pad portion 111, which supports the semiconductor element 20, and the sealing resin 40, thereby improving adhesion between the die pad portion 111 and the sealing resin 40.

The die pad portion 111 also has the sixth protrusions 1114d, the seventh protrusions 1115d, and the eighth protrusions 1116d. Each sixth protrusion 1114d protrudes from the second side surface 1114 toward the x2 side in the first direction x. The sixth protrusions 1114d are arranged at intervals in the second direction y. Each seventh protrusion 1115d protrudes from the third side surface 1115 toward the y1 side in the second direction y. The seventh protrusions 1115d are arranged at intervals in the first direction x. Each eighth protrusion 1116d protrudes from the fourth side surface 1116 toward the y2 side in the second direction y. The eighth protrusions 1116d are arranged at intervals in the first direction x. Providing the die pad portion 111 with the sixth protrusions 1114d, seventh protrusions 1115d, and eighth protrusions 1116d described above efficiently increases the contact area between the die pad portion 111, which supports the semiconductor element 20, and the sealing resin 40, thereby improving adhesion between the die pad portion 111 and the sealing resin 40.

Each fifth protrusion 1113d is not in contact with either the first corner 1117a or the second corner 1117b. Similarly, each sixth protrusion 1114d is not in contact with either the third corner 1117c or the fourth corner 1117d. Each seventh protrusion 1115d is not in contact with either the first corner 1117a or the third corner 1117c. Each eighth protrusion 1116d is not in contact with either the second corner 1117b or the fourth corner 1117d. This configuration prevents peeling of the sealing resin 40 at the four corners (the first to fourth corners 1117a to 1117d) of the die pad portion 111. This is desirable for improving adhesion between the die pad portion 111 and the sealing resin 40.

In the semiconductor device A20, the respective fifth to eighth protrusions 1113d to 1116d are all covered with the sealing resin 40. Thus, as shown in FIG. 27, the rectangular first reverse surface 1112 of the die pad portion 111 is exposed from the sealing resin 40 on the z2 side in the thickness direction z. Thus, the appearance of the semiconductor device A20 remains unchanged compared to conventional devices when the die pad portion 111 is seen from the z2 side in the thickness direction z.

### First Variation of Second Embodiment

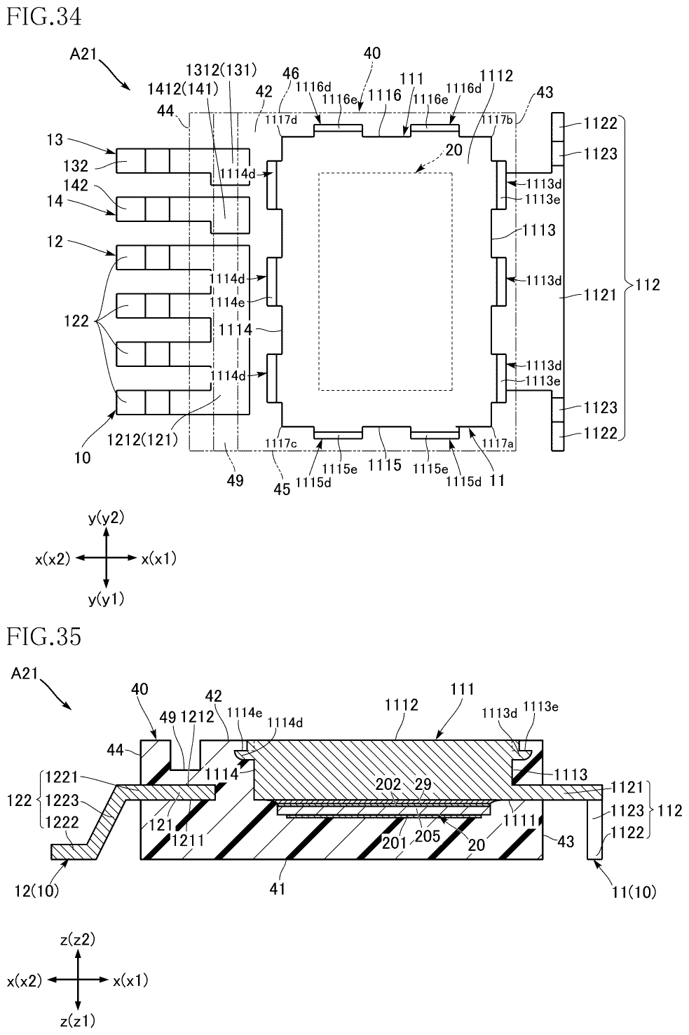

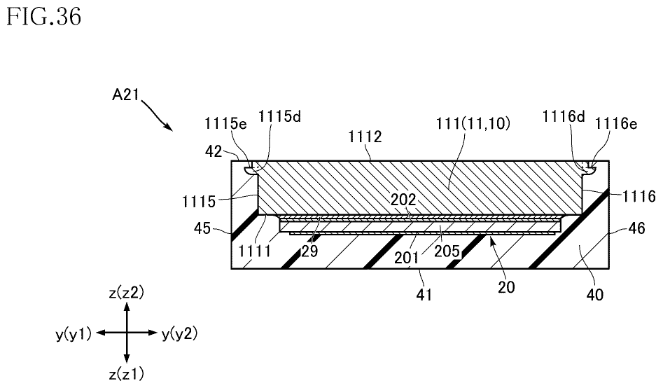

FIGS. 33 to 36 show a first variation of the semiconductor device A20. FIG. 33 is a perspective view of the main portion of a semiconductor device A21 according to this variation. FIG. 34 is a plan view of the main portion of the semiconductor device A21. In FIGS. 33 and 34, the outline of the sealing resin 40 is indicated by an imaginary line (dash-double-dot line). FIG. 35 is a sectional view of the semiconductor device A21, corresponding to the section shown in FIG. 31. FIG. 36 is a sectional view of the semiconductor device A21, corresponding to the section shown in FIG. 32. The semiconductor device A21 of this variation differs from the semiconductor device A20 in the shapes of the fifth protrusions 1113d, sixth protrusions 1114d, seventh protrusions 1115d, and seventh protrusions 1115d of the die pad portion 111.

For the semiconductor device A21, the respective fifth to eighth protrusions 1113d to 1116d each have a portion connected to the first reverse surface 1112. The fifth to eighth protrusions 1113d to 1116d of this variation can be formed by pressing the first reverse surface 1112 of the die pad portion 111 toward the z1 side in the thickness direction z. In this variation, the pressing is applied to the respective projections at locations outside the edges of the first reverse surface 1112.

In the semiconductor device A21, the die pad portion 111, which supports the semiconductor element 20, has the fifth protrusions 1113d. Each fifth protrusion 1113d protrudes from the first side surface 1113 toward the x1 side in the first direction x. The fifth protrusions 1113d are arranged at intervals in the second direction y. Providing the die pad portion 111 with the fifth protrusions 1113d described above efficiently increases the contact area between the die pad portion 111, which supports the semiconductor element 20, and the sealing resin 40, thereby improving adhesion between the die pad portion 111 and the sealing resin 40. Additionally, the semiconductor device A21 achieves the same advantages as the semiconductor device A20 of the above-described embodiment within the scope of configurations similar to semiconductor device A20.

The semiconductor devices according to the present disclosure are not limited to the foregoing embodiments. Various modifications in design may be made freely in the specific structure of each part of the semiconductor devices according to the present disclosure. In addition, the package of each semiconductor device according to the present disclosure is not limited to the one shown for the semiconductor device A10. Various other packages can be employed in the present disclosure.

The present disclosure includes embodiments described in the following clauses.

### Clause 1.

A semiconductor device comprising:
a semiconductor element;
a first lead that includes a die pad portion; and
a sealing resin that covers the semiconductor element and a portion of the first lead,
wherein the die pad portion includes a first obverse surface facing a first side in a thickness direction and supporting the semiconductor element, a first reverse surface facing a second side in the thickness direction, a first side surface facing a first side in a first direction perpendicular to the thickness direction, and a plurality of first recesses each recessed from both the first reverse surface and the first side surface,
the first reverse surface is exposed from the sealing resin, and
the plurality of first recesses are arranged at intervals in a second direction perpendicular to the thickness direction and the first direction.

### Clause 2.

The semiconductor device according to Clause 1, wherein each of the plurality of first recesses includes a first intermediate surface facing the second side in the thickness direction.

### Clause 3.

The semiconductor device according to Clause 1 or 2, wherein a first dimension is spacing between two immediately adjacent first recesses in the second direction, a second dimension is a length of one of the first recesses measured in the second direction, and the first dimension is one-fifth to five times the second dimension.

### Clause 4.

The semiconductor device according to any one of Clauses 1 to 3, wherein the die pad portion includes three or more first recesses, and
the plurality of first recesses are arranged at intervals in the second direction.

### Clause 5.

The semiconductor device according to any one of Clauses 1 to 4, wherein the die pad portion includes a plurality of first protrusions each connected to one of the plurality of first recesses and protruding from the first side surface toward the first side in the first direction.

### Clause 6.

The semiconductor device according to any one of Clauses 1 to 5, wherein the die pad portion includes a second side surface facing a second side in the first direction, a third side surface facing a first side in the second direction, a fourth side surface facing a second side in the second direction, a plurality of second recesses each recessed from both the first reverse surface and the second side surface, a plurality of third recesses each recessed from both the first reverse surface and the third side surface, and a plurality of fourth recesses each recessed from both the first reverse surface and the fourth side surface,
the plurality of second recesses are arranged at intervals in the second direction,
the plurality of third recesses are arranged at intervals in the first direction, and
the plurality of fourth recesses are arranged at intervals in the first direction.

### Clause 7.

The semiconductor device according to Clause 6, wherein each of the plurality of second recesses includes a second intermediate surface facing the second side in the thickness direction,
each of the plurality of third recesses includes a third intermediate surface facing the second side in the thickness direction, and
each of the plurality of fourth recesses includes a fourth intermediate surface facing the second side in the thickness direction.

### Clause 8.

The semiconductor device according to Clause 6 or 7, wherein a third dimension is spacing between two immediately adjacent second recesses in the second direction, a fourth dimension is a length of one of the second recesses measured in the second direction, and the third dimension is one-fifth to five times the fourth dimension,
a fifth dimension is spacing between two immediately adjacent third recesses in the first direction, a sixth dimension is a length of one of the third recesses measured in the first direction, and the fifth dimension is one-fifth to five times the sixth dimension, and
a seventh dimension is spacing between two immediately adjacent fourth recesses in the first direction, an eighth dimension is a length of one of the fourth recesses measured in the first direction, and the seventh dimension is one-fifth to five times the eighth dimension.

### Clause 9.

The semiconductor device according to any one of Clauses 6 to 8, wherein the die pad portion includes three or more second recesses, three or more third recesses, and three or more fourth recesses,
the plurality of second recesses are arranged at intervals in the second direction,
the plurality of third recesses are arranged at intervals in the first direction, and
the plurality of fourth recesses are arranged at intervals in the first direction.

### Clause 10.

The semiconductor device according to any one of Clauses 6 to 9, wherein the die pad portion includes a plurality of second protrusions each connected to one of the plurality of second recesses and protruding from the second side surface toward the second side in the first direction, a plurality of third protrusions each connected to one of the plurality of third recesses and protruding from the third side surface toward the first side in the second direction, and a plurality of fourth protrusions each connected to one of the plurality of fourth recesses and protruding from the fourth side surface toward the second side in the second direction.

### Clause 11.

The semiconductor device according to any one of Clauses 6 to 10, wherein the die pad portion includes a first corner where the first side surface and the third side surface meet, a second corner where the first side surface and the fourth side surface meet, a third corner where the second side surface and the third side surface meet, and a fourth corner where the second side surface and the fourth side surface meet,
each of the plurality of first recesses is not in contact with either the first corner or the second corner,
each of the plurality of second recesses is not in contact with either the third corner or the fourth corner,
each of the plurality of third recesses is not in contact with either the first corner or the third corner, and
each of the plurality of fourth recesses is not in contact with either the second corner or the fourth corner.

### Clause 12.

The semiconductor device according to any one of Clauses 6 to 11, wherein as viewed in the thickness direction, the semiconductor element does not overlap any of the plurality of first, second, third, and fourth recesses.

### Clause 13.

The semiconductor device according to any one of Clauses 1 to 12, wherein the semiconductor element includes a first electrode and a third electrode disposed on the first side in the thickness direction, and a second electrode disposed on the second side in the thickness direction, and
the second electrode is electrically bonded to the first obverse surface.

### Clause 14.

The semiconductor device according to Clause 13, wherein the semiconductor element comprises a switching element that includes a drain electrode, a source electrode, and a gate electrode, and
the first electrode comprises the source electrode, the second electrode comprises the drain electrode, and the third electrode comprises the gate electrode.

### Clause 15.

A vehicle comprising a power conversion device that includes the semiconductor device of Clause 14.

### Clause 16.

A semiconductor device comprising:
a semiconductor element;
a first lead that includes a die pad portion; and
a sealing resin that covers the semiconductor element and a portion of the first lead,
wherein the die pad portion includes a first obverse surface facing a first side in a thickness direction and supporting the semiconductor element, a first reverse surface facing a second side in the thickness direction, a first side surface facing a first side in a first direction perpendicular to the thickness direction, and a plurality of fifth protrusions each protruding from the first side surface toward the first side in the first direction,
the first reverse surface is exposed from the sealing resin, and
the plurality of fifth protrusions are positioned proximate to an end of the first side surface on the second side in the thickness direction and are arranged at intervals in a second direction perpendicular to the thickness direction and the first direction.

### Clause 17.

The semiconductor device according to Clause 16, wherein each of the plurality of fifth protrusions includes a fifth intermediate surface facing the second side in the thickness direction.

### Clause 18.

The semiconductor device according to Clause 16 or 17, wherein the die pad portion includes a second side surface facing a second side in the first direction, a third side surface facing a first side in the second direction, a fourth side surface facing a second side in the second direction, a plurality of sixth protrusions each protruding from the second side surface toward the second side in the first direction, a plurality of seventh protrusions each protruding from the third side surface toward the first side in the second direction, and a plurality of eighth protrusions each protruding from the fourth side surface toward the second side in the second direction,
the plurality of sixth protrusions are positioned proximate to an end of the second side surface on the second side in the thickness direction and are arranged at intervals in the second direction,
the plurality of seventh protrusions are positioned proximate to an end of the third side surface on the second side in the thickness direction and are arranged at intervals in the first direction, and
the plurality of eighth protrusions are positioned proximate to an end of the fourth side surface on the second side in the thickness direction and are arranged at intervals in the first direction.

### Clause 19.

The semiconductor device according to Clause 18, wherein each of the plurality of sixth protrusions includes a sixth intermediate surface facing the second side in the thickness direction,
each of the plurality of seventh protrusions includes a seventh intermediate surface facing the second side in the thickness direction, and
each of the plurality of eighth protrusions includes an eighth intermediate surface facing the second side in the thickness direction.

### Clause 20.

The semiconductor device according to Clause 18 or 19, wherein the die pad portion includes a first corner where the first side surface and the third side surface meet, a second corner where the first side surface and the fourth side surface meet, a third corner where the second side surface and the third side surface meet, and a fourth corner where the second side surface and the fourth side surface meet,
each of the plurality of fifth protrusions is not in contact with either the first corner or the second corner,
each of the plurality of sixth protrusions is not in contact with either the third corner or the fourth corner,
each of the plurality of seventh protrusions is not in contact with either the first corner or the third corner, and
each of the plurality of eighth protrusion is not in contact with either the second corner or the fourth corner.

REFERENCE NUMERALS

| | |
|---|---|
| A10, A11, A12, A20, A21: | |
| semiconductor device | |
| B1: vehicle | 10: conductive member |
| 11: first lead | 111: die pad portion |
| 1111: first obverse surface | 1112: first reverse surface |
| 1113: first side surface | 1113a: first recess |
| 1113b: first intermediate surface | 1113c: first protrusion |
| 1113d: fifth protrusion | 1113e: fifth intermediate surface |
| 1114: second side surface | 1114a: second recess |
| 1114b: second intermediate surface | 1114c: second protrusion |
| 1114d: sixth protrusion | 1114e: sixth intermediate surface |
| 1115: third side surface | 1115a: third recess |
| 1115b: third intermediate surface | 1115c: third protrusion |
| 1115d: seventh protrusion | 1115e: seventh intermediate surface |
| 1116: fourth side surface | 1116a: fourth recess |
| 1116b: fourth intermediate surface | 1116c: fourth protrusion |
| 1116d: eighth protrusion | 1116e: eighth intermediate surface |
| 1117a: first corner | 1117b: second corner |
| 1117c: third corner | 1117d: fourth corner |
| 112: first terminal portion | 1121: first section |
| 1122: second section | 1123: third section |
| 113: connecting portion | 12: second lead |
| 121: pad portion | 122: second terminal portion |
| 1211: second obverse surface | 1212: second reverse surface |
| 1221: fourth section | 1222: fifth section |
| 1223: sixth section | 13: third lead |
| 131: pad portion | 132: third terminal portion |
| 1311: third obverse surface | 1312: third reverse surface |
| 1321: seventh section | 1322: eighth section |
| 1323: ninth section | 14: fourth lead |
| 141: pad portion | 142: fourth terminal portion |
| 1411: fourth obverse surface | 1412: fourth reverse surface |
| 1421: tenth section | 1422: eleventh section |
| 1423: twelfth section | 20: semiconductor element |
| 201: first electrode | 202: second electrode |
| 203: third electrode | 205: semiconductor layer |
| 29: bonding layer | 31: connecting member |
| 32: connecting member | 33: connecting member |
| 40: sealing resin | 41: first resin surface |
| 42: second resin surface | 43: third resin surface |
| 44: fourth resin surface | 45: fifth resin surface |
| 46: sixth resin surface | 49: groove |
| 80: charging station | 81: AC-DC converter |
| | (power conversion device) |
| 82: power receiver | 83: storage battery |
| 84: drive system | 91: heatsink |
| 92: circuit board | 919: sheet material |
| 921: solder | L1: first dimension |
| L2: second dimension | L3: third dimension |
| L4: fourth dimension | L5: fifth dimension |
| L6: sixth dimension | L7: seventh dimension |
| L8: eighth dimension | |

1. A semiconductor device comprising:
a semiconductor element;
a first lead that includes a die pad portion; and
a sealing resin that covers the semiconductor element and a portion of the first lead,
wherein the die pad portion includes a first obverse surface facing a first side in a thickness direction and supporting the semiconductor element, a first reverse surface facing a second side in the thickness direction, a first side surface facing a first side in a first direction perpendicular to the thickness direction, and a plurality of first recesses each recessed from both the first reverse surface and the first side surface,
the first reverse surface is exposed from the sealing resin, and
the plurality of first recesses are arranged at intervals in a second direction perpendicular to the thickness direction and the first direction.

2. The semiconductor device according to claim 1, wherein each of the plurality of first recesses includes a first intermediate surface facing the second side in the thickness direction.

3. The semiconductor device according to claim 1, wherein a first dimension is spacing between two immediately adjacent first recesses in the second direction, a second dimension is a length of one of the first recesses measured in the second direction, and the first dimension is one-fifth to five times the second dimension.

4. The semiconductor device according to claim 1, wherein the die pad portion includes three or more first recesses, and
the plurality of first recesses are arranged at intervals in the second direction.

5. The semiconductor device according to claim 1, wherein the die pad portion includes a plurality of first protrusions each connected to one of the plurality of first recesses and protruding from the first side surface toward the first side in the first direction.

6. The semiconductor device according to claim 1, wherein the die pad portion includes a second side surface facing a second side in the first direction, a third side surface facing a first side in the second direction, a fourth side surface facing a second side in the second direction, a plurality of second recesses each recessed from both the first reverse surface and the second side surface, a plurality of third recesses each recessed from both the first reverse surface and the third side surface, and a plurality of fourth recesses each recessed from both the first reverse surface and the fourth side surface,
the plurality of second recesses are arranged at intervals in the second direction,
the plurality of third recesses are arranged at intervals in the first direction, and
the plurality of fourth recesses are arranged at intervals in the first direction.

7. The semiconductor device according to claim 6, wherein each of the plurality of second recesses includes a second intermediate surface facing the second side in the thickness direction,
each of the plurality of third recesses includes a third intermediate surface facing the second side in the thickness direction, and
each of the plurality of fourth recesses includes a fourth intermediate surface facing the second side in the thickness direction.

8. The semiconductor device according to claim 6, wherein a third dimension is spacing between two immediately adjacent second recesses in the second direction, a fourth dimension is a length of one of the second recesses measured in the second direction, and the third dimension is one-fifth to five times the fourth dimension,
a fifth dimension is spacing between two immediately adjacent third recesses in the first direction, a sixth dimension is a length of one of the third recesses measured in the first direction, and the fifth dimension is one-fifth to five times the sixth dimension, and
a seventh dimension is spacing between two immediately adjacent fourth recesses in the first direction, an eighth dimension is a length of one of the fourth recesses measured in the first direction, and the seventh dimension is one-fifth to five times the eighth dimension.

9. The semiconductor device according to claim 6, wherein the die pad portion includes three or more second recesses, three or more third recesses, and three or more fourth recesses,
the plurality of second recesses are arranged at intervals in the second direction,
the plurality of third recesses are arranged at intervals in the first direction, and
the plurality of fourth recesses are arranged at intervals in the first direction.

10. The semiconductor device according to claim 6, wherein the die pad portion includes a plurality of second protrusions each connected to one of the plurality of second recesses and protruding from the second side surface toward the second side in the first direction, a plurality of third protrusions each connected to one of the plurality of third recesses and protruding from the third side surface toward the first side in the second direction, and a plurality of fourth protrusions each connected to one of the plurality of fourth recesses and protruding from the fourth side surface toward the second side in the second direction.

11. The semiconductor device according to claim 6, wherein the die pad portion includes a first corner where the first side surface and the third side surface meet, a second corner where the first side surface and the fourth side surface meet, a third corner where the second side surface and the third side surface meet, and a fourth corner where the second side surface and the fourth side surface meet,
each of the plurality of first recesses is not in contact with either the first corner or the second corner,
each of the plurality of second recesses is not in contact with either the third corner or the fourth corner,
each of the plurality of third recesses is not in contact with either the first corner or the third corner, and
each of the plurality of fourth recesses is not in contact with either the second corner or the fourth corner.

12. The semiconductor device according to claim 6, wherein as viewed in the thickness direction, the semiconductor element does not overlap any of the plurality of first, second, third, and fourth recesses.

13. The semiconductor device according to claim 1, wherein the semiconductor element includes a first electrode and a third electrode disposed on the first side in the thickness direction, and a second electrode disposed on the second side in the thickness direction, and
the second electrode is electrically bonded to the first obverse surface.

14. The semiconductor device according to claim 13, wherein the semiconductor element comprises a switching element that includes a drain electrode, a source electrode, and a gate electrode, and
the first electrode comprises the source electrode, the second electrode comprises the drain electrode, and the third electrode comprises the gate electrode.

15. A vehicle comprising a power conversion device that includes the semiconductor device of claim 14.

16. A semiconductor device comprising:
a semiconductor element;
a first lead that includes a die pad portion; and
a sealing resin that covers the semiconductor element and a portion of the first lead,
wherein the die pad portion includes a first obverse surface facing a first side in a thickness direction and supporting the semiconductor element, a first reverse surface facing a second side in the thickness direction, a first side surface facing a first side in a first direction perpendicular to the thickness direction, and a plurality of fifth protrusions each protruding from the first side surface toward the first side in the first direction,
the first reverse surface is exposed from the sealing resin, and
the plurality of fifth protrusions are positioned proximate to an end of the first side surface on the second side in the thickness direction and are arranged at intervals in a second direction perpendicular to the thickness direction and the first direction.

17. The semiconductor device according to claim 16, wherein each of the plurality of fifth protrusions includes a fifth intermediate surface facing the second side in the thickness direction.

18. The semiconductor device according to claim 16, wherein the die pad portion includes a second side surface facing a second side in the first direction, a third side surface facing a first side in the second direction, a fourth side surface facing a second side in the second direction, a plurality of sixth protrusions each protruding from the second side surface toward the second side in the first direction, a plurality of seventh protrusions each protruding from the third side surface toward the first side in the second direction, and a plurality of eighth protrusions each protruding from the fourth side surface toward the second side in the second direction,
the plurality of sixth protrusions are positioned proximate to an end of the second side surface on the second side in the thickness direction and are arranged at intervals in the second direction,
the plurality of seventh protrusions are positioned proximate to an end of the third side surface on the second side in the thickness direction and are arranged at intervals in the first direction, and
the plurality of eighth protrusions are positioned proximate to an end of the fourth side surface on the second side in the thickness direction and are arranged at intervals in the first direction.

19. The semiconductor device according to claim 18, wherein each of the plurality of sixth protrusions includes a sixth intermediate surface facing the second side in the thickness direction,
each of the plurality of seventh protrusions includes a seventh intermediate surface facing the second side in the thickness direction, and
each of the plurality of eighth protrusions includes an eighth intermediate surface facing the second side in the thickness direction.

20. The semiconductor device according to claim 18, wherein the die pad portion includes a first corner where the first side surface and the third side surface meet, a second corner where the first side surface and the fourth side surface meet, a third corner where the second side surface and the third side surface meet, and a fourth corner where the second side surface and the fourth side surface meet,
each of the plurality of fifth protrusions is not in contact with either the first corner or the second corner,
each of the plurality of sixth protrusions is not in contact with either the third corner or the fourth corner,
each of the plurality of seventh protrusions is not in contact with either the first corner or the third corner, and
each of the plurality of eighth protrusion is not in contact with either the second corner or the fourth corner.
